(19) United States
(12) Patent Application Publication
(10) Pub. No.: US 2025/0199953 A1
(43) Pub. Date: Jun. 19, 2025

(54) MEMORY SYSTEM AND SEMICONDUCTOR MEMORY DEVICE

(71) Applicant: Kioxia Corporation, Tokyo (JP)

(72) Inventors: Dongxu LI, Kawasaki Kanagawa (JP); Kiyotaro ITAGAKI, Ota Tokyo (JP)

(21) Appl. No.: 18/981,144

(22) Filed: Dec. 13, 2024

(30) Foreign Application Priority Data
Dec. 18, 2023 (JP) 2023-213208

(51) Int. Cl. G06F 12/02

(52) U.S. Cl. CPC G06F 12/0246

(57) ABSTRACT

A memory system includes first and second memory chips, each including first and second pads, a phase adjustment circuit, and a control circuit. The first pads of the memory chips are commonly connected and the second pads of the memory chips are commonly connected. In response to a first command set for the first memory chip to read data and a second command set for the second memory chip to write data, the control circuit of the first memory chip reads and outputs a data signal through its first pad along with a timing signal output through its second pad, and concurrently therewith, the control circuit of the second memory chip receives the data through its first pad with reference to a timing signal received through its second pad and writes the data thereinto.

### CROSS-REFERENCE TO RELATED APPLICATION(S)

This application is based upon and claims the benefit of priority from Japanese Patent Application No. 2023-213208, filed Dec. 18, 2023, the entire contents of which are incorporated herein by reference.

### FIELD

Embodiments described herein relate generally to a memory system, and a semiconductor memory device.

### BACKGROUND

A memory system that includes a plurality of memory chips is known. Each of the memory chips includes a memory cell array.

### BRIEF DESCRIPTION OF THE DRAWINGS

FIG. 1 is a schematic block diagram showing the configuration of a memory system according to a first embodiment.

FIG. 2 is a side view of a configuration example of a package included in the memory system.

FIG. 3 is a plan view of the configuration example of the package PKG included in the memory system.

FIG. 4 is a schematic side view showing the configuration example of the memory system.

FIG. 5 is a schematic block diagram showing the configuration of a memory die.

FIG. 6 is a schematic circuit diagram showing the configuration of part of the memory die.

FIG. 7 is a schematic perspective view showing the configuration of part of the memory die.

FIG. 8 is a schematic circuit diagram showing the configuration of part of the memory die.

FIG. 9 is a schematic circuit diagram showing the configuration of part of the memory die.

FIG. 10 is a schematic diagram for illustrating roles of signal input and output terminals and control terminals of the memory die.

FIG. 11 is a schematic waveform diagram for illustrating the operation of the memory die.

FIG. 12 is a schematic table for illustrating the operation of the memory die.

FIG. 13 is a schematic waveform diagram for illustrating a read operation.

FIG. 14 is a schematic waveform diagram for illustrating data output.

FIG. 15 is a schematic waveform diagram for illustrating a write operation.

FIGS. 16-18 are each a schematic block diagram for illustrating an inter-chip copy operation.

FIGS. 19-20 are each a schematic waveform diagram for illustrating the inter-chip copy operation.

FIGS. 21-24 are each a schematic waveform diagram for illustrating the role of a phase adjustment circuit in the inter-chip copy operation.

FIG. 25 is a schematic block diagram showing the configuration of a memory die according to a second embodiment.

FIG. 26 is a schematic circuit diagram showing the configuration of part of the memory die.

FIGS. 27-29 are each a schematic block diagram for illustrating an inter-plane copy operation.

FIG. 30 is a schematic waveform diagram for illustrating the inter-plane copy operation.

### DETAILED DESCRIPTION

In general, according to one embodiment, a memory system includes a controller and a plurality of memory chips. Each of the memory chips includes a memory cell array, a first pad electrode, a second pad electrode, a phase adjustment circuit, and a control circuit. The first pad electrodes of the memory chips are commonly connected to a first pad electrode of the controller and the second pad electrodes of the memory chips are commonly connected to a second pad electrode of the controller. In response to a first command set input into a first memory chip among the memory chips to read data, and a second command set input into a second memory chip among the memory chips to write data, the control circuit of the first memory chip executes reading of data from the memory cell array of the first memory chip and outputting of a data signal containing the read data through the first pad electrode of the first memory chip along with a timing signal output through the second pad electrode of the first memory chip, and concurrently therewith, the control circuit of the second memory chip executes receiving of a data signal containing write data through the first pad electrode of the second memory chip with reference to a timing signal received through the second pad electrode of the second memory chip and writing of the write data into the memory cell array of the second memory chip, and one or both of the phase adjustment circuit of the first memory chip and the phase adjustment circuit of the second memory chip adjust a phase of the data signal or the timing signal.

Hereinafter, a memory system and a semiconductor memory device according to an embodiment are described in detail with reference to the drawings. Note that the following embodiment is only an example, and is not intended to limit the scope of the present invention. For the sake of description, part of the configuration and the like may be omitted. Common portions in embodiments are assigned the same symbols, and their description may be omitted.

In this specification, a “memory system” means a system that includes a plurality of memory dies (or memory chips), and a controller die (or controller chip). The memory system is, for example, a memory card, an SSD (Solid State Drive) or the like in some cases, and may have a configuration that includes a host computer, such as a smartphone, a tablet terminal, or a personal computer, in other cases.

In this specification, the reference to a “semiconductor memory device” means a memory die (or memory chip), and may also mean a memory system that includes a controller die, such as a memory chip, a memory card, or an SSD (Solid State Drive), in other cases. Furthermore, it may have a configuration that includes a host computer, such as a smartphone, a tablet terminal, or a personal computer, in other cases.

In this specification, when it is described that a first configuration is “electrically connected” to a second configuration, the first configuration may be directly connected to the second configuration, and the first configuration may be connected to the second configuration via wiring, a semiconductor member, a transistor or the like. For example, in a case where three transistors are connected in series, the first transistor is “electrically connected” to the third transistor even if the second transistor is in the OFF state.

In this specification, when it is described that the first configuration is “connected between” the second configuration and the third configuration, it may mean that the first configuration, the second configuration, and the third configuration are connected in series, and the second configuration is connected to the third configuration via the first configuration.

In this specification, a predetermined direction in parallel with an upper surface of a substrate is referred to as an X-direction, and a direction that is in parallel with the upper surface of the substrate and is perpendicular to the X-direction is referred to as a Y-direction, and the direction perpendicular to the upper surface of the substrate is referred to as a Z-direction.

### First Embodiment

### Memory System 10

FIG. 1 is a schematic block diagram showing the configuration of a memory system 10 according to a first embodiment.

The memory system 10 performs reading, writing, erasing and the like of user data, according to a signal transmitted from a host computer 20. The memory system 10 is, for example, a memory card, an SSD, or other system that can store the user data. The memory system 10 includes a plurality of packages PKG, and a controller die CD connected to these packages PKG and the host computer 20. Each package PKG includes a plurality of memory dies MD. Each memory die MD can store the user data. The controller die CD includes, for example, a processor and a RAM, and performs processes, such as translation between logical addresses and physical addresses, bit error detection/correction, garbage collection (compaction), and wear leveling.

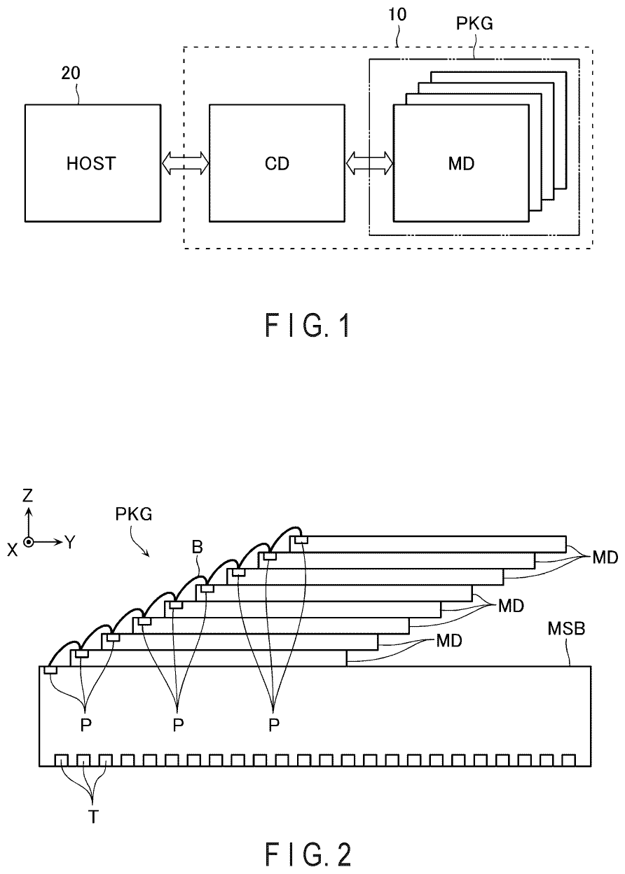

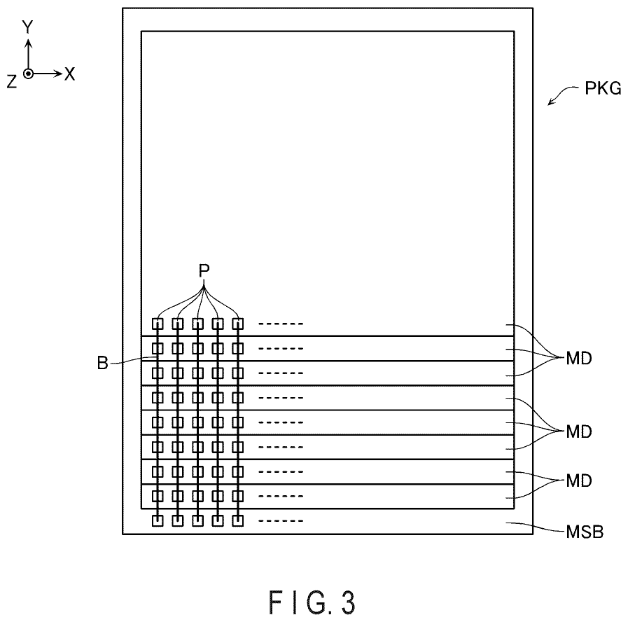

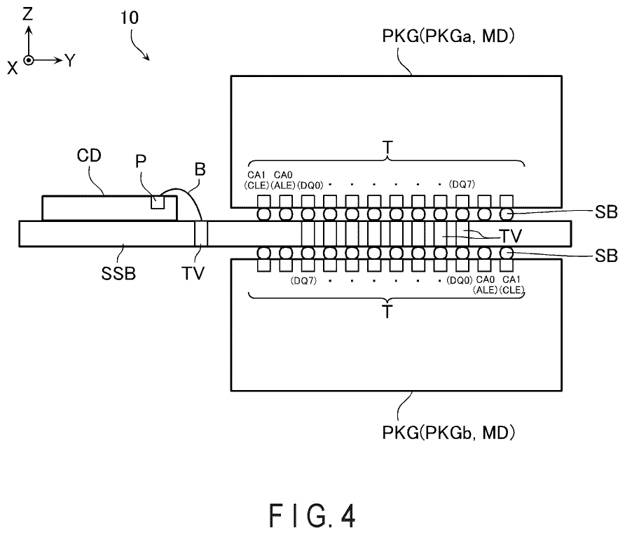

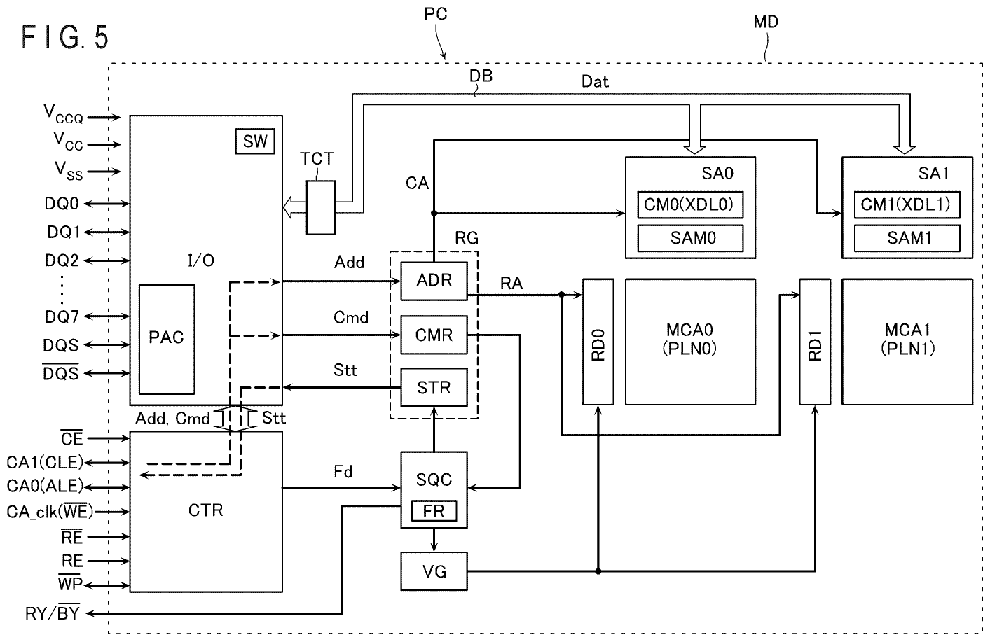

FIGS. 2 and 3 show a configuration example of the package PKG included in the memory system 10 according to the present embodiment. More specifically, FIG. 2 is a schematic side view showing the configuration example of the package PKG, and FIG. 3 is a schematic plan view showing the configuration example of the package PKG. FIG. 4 is a schematic side view showing the configuration example of the memory system 10. For the sake of description, part of the configuration of the package PKG is omitted in FIGS. 2 to 3 and part of the configuration of the memory system 10 is omitted in FIG. 4.

As shown in FIG. 2, the package PKG according to the present embodiment includes a memory die mounting board MSB, and a plurality of memory dies MD stacked on the memory die mounting board MSB. Pad electrodes P are provided in a region at an end in the Y-direction on the upper surface of the memory die mounting board MSB. Another partial region is bonded to the lower surface of a memory die MD with adhesive or the like. Pad electrodes P are provided in a region at an end in the Y-direction on the upper surface of the memory die MD. The other region is bonded to the lower surface of another memory die MD with adhesive or the like. The corresponding pad electrodes P among the memory dies MD are commonly connected to each other by bonding wires B. Electrode terminals T are provided on the lower surface of the memory die mounting board MSB. The pad electrodes P on the upper surface of the memory die mounting board MSB are connected to the corresponding electrode terminals T on the lower surface. The memory die mounting board MSB may be, for example, a grid array substrate. On the upper surface of the memory die mounting board MSB, the memory dies MD and the bonding wires B are covered with encapsulating resin, not shown.

As shown in FIG. 3, the memory die mounting board MSB and the memory dies MD each include the pad electrodes P arranged in the X-direction. The pad electrodes P of each memory die MD correspond to control terminals /CE, CA1(CLE), CA0(ALE), CA_clk(/WE), /RE, RE, and /WP, data signal input and output terminals DQ0 to DQ7, data strobe signal input and output terminals DQS and /DQS, and terminals RY//BY, which are described later with reference to FIG. 5 and the like.

The pad electrodes P provided on the memory die mounting board MSB and the memory dies MD are connected to each other via the bonding wires B. For example, the pad electrodes P corresponding to the control terminals CA1(CLE) on the memory dies MD are connected to each other, and the pad electrodes P corresponding to the control terminals CA0(ALE) are connected to each other. This similarly applies to the other terminals. The pad electrodes P of each memory die MD in the package PKG are connected to the outside of the package PKG via the electrode terminals T on the lower surface of the memory die mounting board MSB.

In the example shown in FIG. 4, the memory system 10 includes a system mounting board SSB, the packages PKG arranged on the system mounting board SSB, and a controller die CD. The controller die CD and some packages PKG are arranged on the upper surface of the system mounting board SSB. The other packages PKG are arranged on the lower surface of the system mounting board SSB.

Pad electrodes P are also provided on the controller die CD. The pad electrodes P of the controller die CD are connected to the system mounting board SSB via the bonding wires B. The electrode terminals T of the packages PKG are connected to the system mounting board SSB via solder balls SB. The pad electrodes P of the controller die CD and the electrode terminals T of the packages PKG are connected to each other by wires, not shown, formed on the upper surface and the lower surface of the system mounting board SSB. The upper surface and the lower surface of the system mounting board SSB are connected to each other by through vias TV.

Some of the electrode terminals T of the package PKG disposed on the upper surface of the system mounting board SSB, and some of the electrode terminals T of the package PKG disposed on the lower surface of the system mounting board SSB may be connected by the through vias TV. More specifically, the electrode terminals T corresponding to the data signal input and output terminals DQ0 to DQ7 of the package PKG disposed on the upper surface of the system mounting board SSB, and the electrode terminals T corresponding to the data signal input and output terminals DQ0 to DQ7 of the package PKG disposed on the lower surface of the system mounting board SSB are connected to each other through the through vias TV.

In the case where the packages PKG have the same configuration, for example, the electrode terminal T corresponding to the data signal input and output terminal DQ0 on one package PKG is connected to the electrode terminal T corresponding to the data signal input and output terminal DQ7 on the other package PKG (FIG. 4). Here, the one package PKG is referred to as a forward connection package PKGa, and the other package PKG is referred to as a reverse connection package PKGb. The electrode terminals T of the forward connection package PKGa that correspond to the data signal input and output terminals DQ1, DQ2, DQ3, DQ4, DQ5, DQ6, and DQ7 are respectively connected to the electrode terminals T of the reverse connection package PKGb that correspond to the data signal input and output terminals DQ6, DQ5, DQ4, DQ3, DQ2, DQ1, and DQ0. Such a connection scheme is referred to as a mirror connection.

Note that the electrode terminals T corresponding to the other electrode terminals are individually connected to the corresponding pad electrodes P of the controller die CD. For example, the electrode terminal T of the one package PKG (forward connection package PKGa) that corresponds to the control terminal CA1(CLE), and the electrode terminal T of the other package PKG (reverse connection package PKGb) that corresponds to the control terminal CA1(CLE) are connected to the pad electrodes P of the controller die CD by wires different from each other. The electrode terminal T of the one package PKG (forward connection package PKGa) that corresponds to the control terminal CA0(ALE), and the electrode terminal T of the other package PKG (reverse connection package PKGb) that corresponds to the control terminal CA0(CLE) are connected to the pad electrodes P of the controller die CD by wires different from each other.

Note that the configuration shown in FIGS. 2 to 4 is only an example. The specific configuration can be appropriately adjusted. For instance, in the example shown in FIGS. 2 and 3, the memory dies MD are stacked, and these components are connected to each other by the bonding wires B. However, the memory dies MD may be connected to each other via the through vias or the like instead of the bonding wires B. In the example shown in FIG. 4, the example where the electrode terminals T (data signal input and output terminals DQ0 to DQ7) of the packages PKG disposed on the upper and lower surfaces of the system mounting board SSB are mirror-connected by the through vias TV is shown. However, the electrode terminals T (data signal input and output terminals DQ0 to DQ7) of the packages PKG are not necessarily mirror-connected.

### Configuration of Memory Die MD

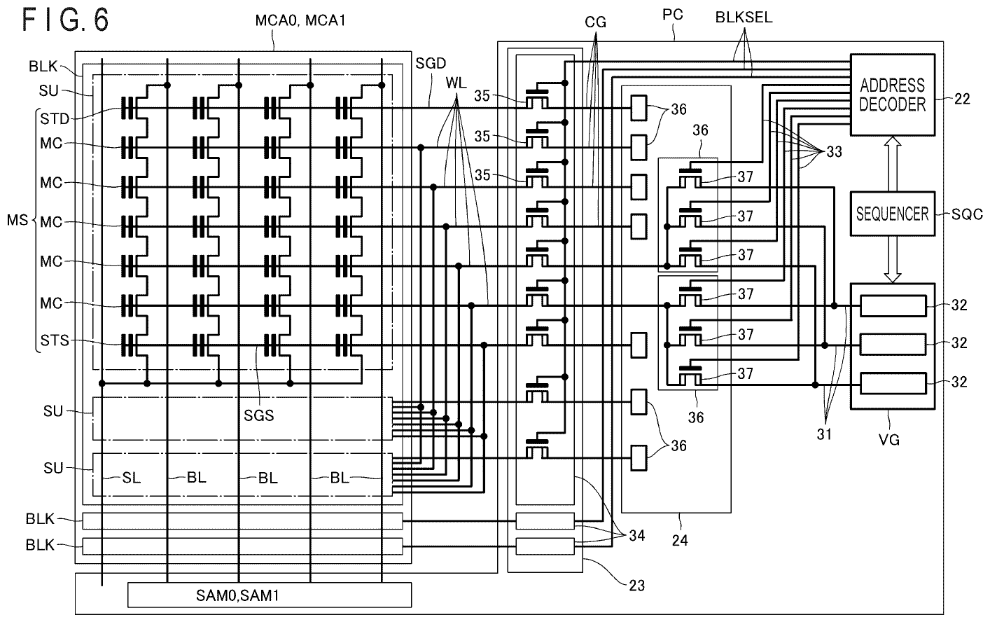

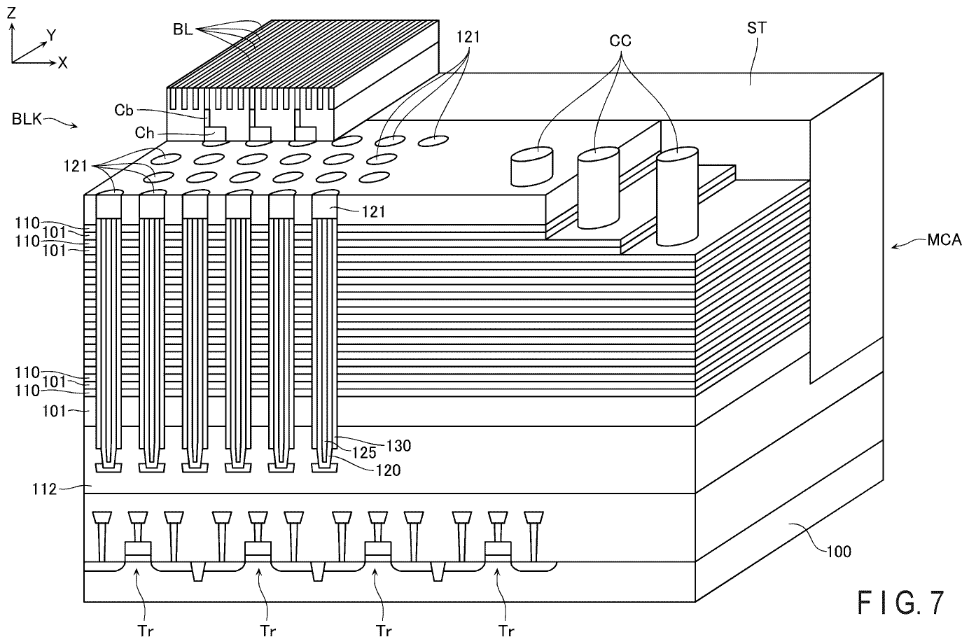

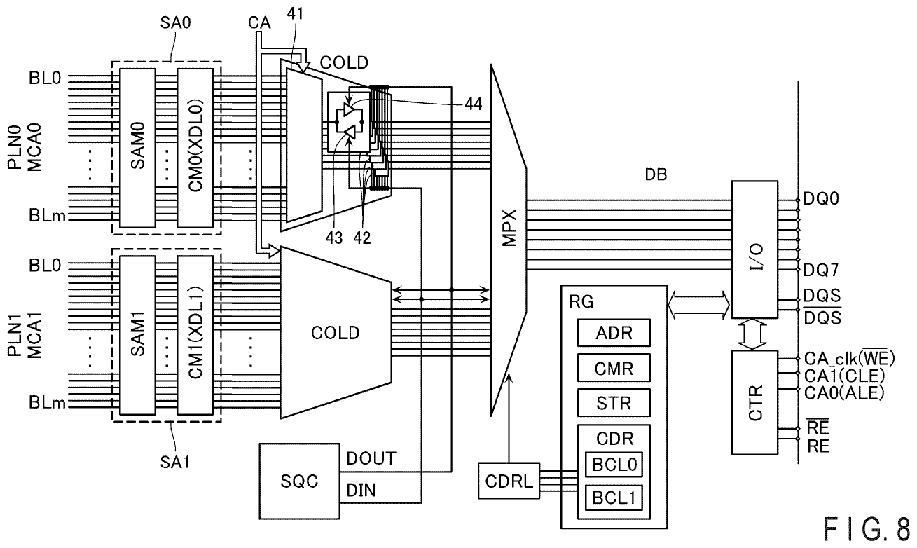

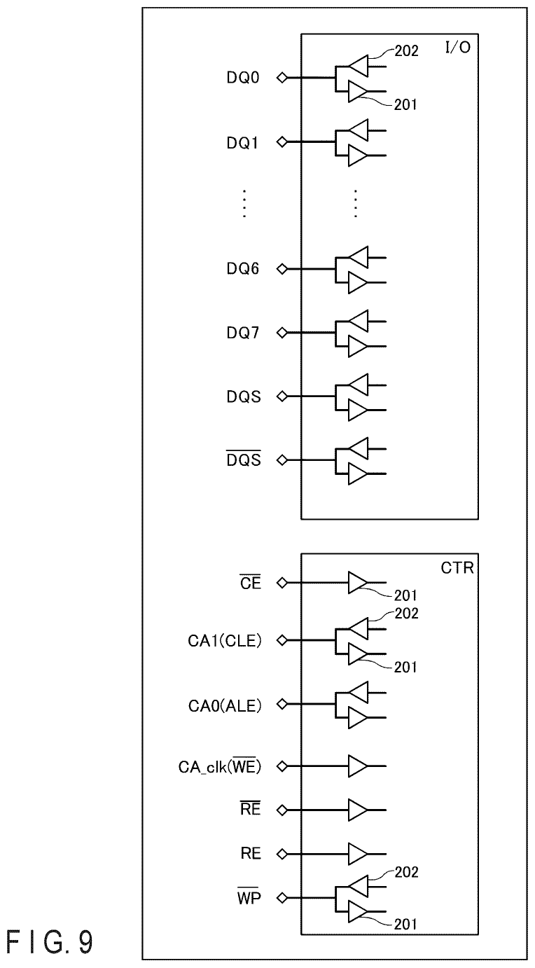

FIG. 5 is a schematic block diagram showing the configuration of a memory die MD according to the first embodiment. FIG. 6 is a schematic circuit diagram showing the configuration of part of the memory die MD. FIG. 7 is a schematic perspective view showing the configuration of part of the memory die MD. FIGS. 8 and 9 are schematic circuit diagrams showing the configuration of part of the memory die MD. For the sake of description, part of configuration of the memory die MD is omitted in FIGS. 5 to 9.

Note that FIG. 5 shows a plurality of control terminals and the like. These control terminals are represented as control terminals corresponding to a high-active signal (positive logic signal) in one case, represented as control terminals corresponding to a low-active signal (negative logic signal) in another case, and represented as control terminals corresponding to both a high-active signal and a low-active signal in still another case. In FIG. 5, the sign of the control terminal corresponding to the low-active signal includes an overline (overbar). In this specification, the sign of each control terminal corresponding to the low-active signal includes a diagonal (“/”). Note that the illustration in FIG. 5 is an example. The specific implementation can be appropriately adjusted. For example, some or all of the high-active signals may be low-active signals, and some or all of the low-active signals may be high-active signals.

On a side of each of the control terminals, an arrow indicating the input/output direction is indicated. In FIG. 5, the control terminal assigned an arrow from the left to the right can be used to input data or another signal from the controller die CD to the memory die MD. In FIG. 5, the control terminal assigned an arrow from the right to the left can be used to output data or another signal from the memory die MD to the controller die CD. In FIG. 5, the control terminal assigned a bidirectional left/right arrow can be used to input data or another signal from the controller die CD to the memory die MD and to output data and another signal from the memory die MD to the controller die CD.

As shown in FIG. 5, the memory die MD includes memory cell arrays MCA0 and MCA1 that store user data, and a peripheral circuit PC connected to the memory cell arrays MCA0 and MCA1. Note that in the following description, the memory cell arrays MCA0 and MCA1 may be referred to as the memory cell array MCA. The memory cell arrays MCA0 and MCA1 may also be referred to as planes PLN0 and PLN1.

### Configuration of Memory Cell Array MCA

As shown in FIG. 6, the memory cell array MCA includes a plurality of memory blocks BLK. These memory blocks BLK each include a plurality of string units SU. These string units SU each include a plurality of memory strings MS. Ends of these memory strings MS are connected to the peripheral circuit PC via the bit lines BL. The other ends of these memory strings MS are connected to the peripheral circuit PC via the common source line SL.

The memory string MS includes a drain-side selection transistor STD, a plurality of memory cell transistors (referred to herein as memory cells MC, for short), and a source-side selection transistor STS that are connected in series between the bit line BL and the source line SL. Hereinafter, the drain-side selection transistor STD and the source-side selection transistor STS may be referred to as the selection transistor (STD, STS).

Each memory cell MC is a field-effect transistor that includes a semiconductor layer, a gate insulating layer, and a gate electrode. The semiconductor layer functions as a channel region. The gate insulating layer includes a charge storage film. The threshold voltage of the memory cell MC changes depending on the amount of charge in the charge storage film. The memory cell MC stores single-bit or multi-bit user data. Note that word lines WL are connected respectively to the gate electrodes of the memory cells MC corresponding to one memory string MS. These word lines WL are commonly connected across all the memory strings MS in one memory block BLK.

The selection transistor (STD, STS) is a field-effect transistor that includes a semiconductor layer, a gate insulating layer, and a gate electrode. The semiconductor layer functions as a channel region. Selection gate lines (SGD and SGS) are respectively connected to the gate electrodes of the selection transistors (STD and STS). The drain-side selection gate line SGD is provided in association with the string unit SU, and is commonly connected to all the memory strings MS in the single string unit SU. The source-side selection gate line SGS is commonly connected across all the memory strings MS in the memory block BLK.

For example, as shown in FIG. 7, the memory cell array MCA is provided above a semiconductor substrate 100. Note that in the example in FIG. 7, a plurality of transistors Tr that make up the peripheral circuit PC are provided between the semiconductor substrate 100 and the memory cell array MCA.

The memory cell array MCA includes the memory blocks BLK arranged in the Y-direction. An inter-block insulating layer ST, such as of silicon oxide (SiO₂), is provided between every two memory blocks BLK adjacent to each other in the Y-direction.

The memory block BLK includes a plurality of conductive layers 110 arranged in the Z-direction, a plurality of semiconductor columns 120 extending in the Z-direction, and a plurality of gate insulating layers 130 each arranged between the conductive layers 110 and the corresponding semiconductor column 120.

The conductive layer 110 is a conductive layer that has a substantially plate shape and extends in the X-direction. The conductive layer 110 may include stacked films that include barrier conductive films, such as of titanium nitride (TiN), and metal films, such as of tungsten (W). The conductive layer 110 may include, for example, polysilicon or the like containing impurities, such as phosphorus (P) or boron (B). The insulating layers 101, such as of silicon oxide (SiO₂), are each provided between the conductive layers 110 arranged in the Z-direction.

One or more conductive layers 110 positioned at the lowermost layers among the conductive layers 110 function as the source-side selection gate lines SGS (FIG. 6) and the gate electrodes of the source-side selection transistors STS connected thereto. These conductive layers 110 are electrically independent with respect to each memory block BLK.

The conductive layers 110 disposed above those functioning as the source-side selection gate lines SGS, function as the word lines WL (FIG. 6) and the gate electrodes of the memory cells MC (FIG. 6) connected thereto. These conductive layers 110 are electrically independent with respect to each memory block BLK.

One or more conductive layers 110 disposed above those functioning as the word lines WL, function as the drain-side selection gate lines SGD and the gate electrodes of the drain-side selection transistors STD (FIG. 6) connected thereto. These conductive layers 110 have a smaller width in the Y-direction than the other conductive layers 110.

A semiconductor layer 112 is provided below the conductive layers 110. The semiconductor layer 112 may include, for example, polysilicon or the like containing impurities, such as phosphorus (P) or boron (B). An insulating layer 101, such as of silicon oxide (SiO₂), is provided between the semiconductor layer 112 and the conductive layer 110.

The semiconductor layer 112 functions as the source line SL (FIG. 6). For example, the source line SL is commonly provided for all the memory blocks BLK included in the memory cell array MCA.

For example, as shown in FIG. 7, the semiconductor columns 120 are arranged in the X-direction and the Y-direction in a predetermined pattern. Each semiconductor column 120 functions as channel regions of the memory cells MC and the selection transistors (STD and STS) included in one single memory string MS (FIG. 6). The semiconductor columns 120 are, for example, semiconductor layers, such as of polysilicon (Si). For example, as shown in FIG. 7, the semiconductor columns 120 each have a substantially solid-bottom cylinder shape, at the center of which an insulating layer 125, such as of silicon oxide, is provided. The outer periphery of each semiconductor column 120 is surrounded by the conductive layers 110, and faces the conductive layers 110.

At an upper end of each semiconductor column 120, an impurity region 121 containing an N-type impurity, such as of phosphorus (P), is provided. The impurity regions 121 are connected to the bit lines BL via contacts Ch and contacts Cb.

Gate insulating layers 130 have substantially solid-bottom cylinder shapes that cover the outer peripheries of the respective semiconductor columns 120. Each gate insulating layer 130 includes, for example, a tunnel insulating layer, a charge storage film, and a block insulating layer stacked between the corresponding semiconductor column 120 and the conductive layers 110. The tunnel insulating layer and the block insulating layer are, for example, insulating layers, such as of silicon oxide (SiO₂). The charge storage film is a film, such as of silicon nitride (Si₃N₄), capable of storing charges. The tunnel insulating layer, the charge storage film, and the block insulating layer each have a substantially solid-bottom cylinder shape, and extend in the Z-direction along the outer periphery of the semiconductor column 120 except a contact portion between the semiconductor column 120 and the semiconductor layer 112.

Note that the gate insulating layer 130 may include, for example, a floating gate, such as of polysilicon containing an N- or P-type impurity, as the charge storage film.

At the ends of the conductive layers 110 in the X-direction, contacts CC are provided. The conductive layers 110 are connected to the peripheral circuit PC via these contacts CC. As shown in FIG. 7, each of these contacts CC extends in the Z-direction, and is connected, at their lower ends, to one of the conductive layers 110. The contacts CC may include stacked films that include barrier conductive films, such as of titanium nitride (TiN), and metal films, such as of tungsten (W).

### Configuration of Peripheral Circuit PC

For example, as shown in FIG. 5, the peripheral circuit PC includes row decoders RD0 and RD1 and sense amplifiers SA0 and SA1, which are connected to the memory cell arrays MCA0 and MCA1. For example, as shown in FIG. 8, the peripheral circuit PC includes column decoders COLD respectively connected to the sense amplifiers SA0 and SA1, and a multiplexer MPX connected to the column decoders COLD. For example, as shown in FIG. 5, the peripheral circuit PC includes a voltage generation circuit VG, and a sequencer SQC. The peripheral circuit PC includes an input and output control circuit I/O, a logic circuit CTR, a register circuit RG, and a data output timing adjuster TCT. Note that in the following description, the row decoders RD0 and RD1 are referred to as the row decoder RD, and the sense amplifiers SA0 and SA1 are referred to as the sense amplifier SA in some cases.

### Configuration of Row Decoder RD

For example, as shown in FIG. 6, the row decoder RD (FIG. 5) includes an address decoder 22 that decodes the row address RA (FIG. 5), and a block selecting circuit 23 and a voltage selecting circuit 24 that transfer an operation voltage to the memory cell array MCA in accordance with the output voltage of the address decoder 22.

For example, as shown in FIG. 6, the address decoder 22 includes a plurality of block selecting lines BLKSEL, and a plurality of voltage selecting lines 33. For example, the address decoder 22 acquires the row address RA from the address register ADR (FIG. 5) according to a control signal from the sequencer SQC, decodes the row address RA, brings a predetermined block selection transistor 35 and voltage selection transistor 37 that correspond to the row address RA into an ON state, and brings the other block selection transistors 35 and voltage selection transistors 37 into an OFF state. For example, the voltages of the predetermined block selecting line BLKSEL and voltage selecting lines 33 are brought into the “H” state, and the other voltages are brought into the “L” state. Note that in the case of using P-channel transistors instead of N-channel ones, reverse voltages are applied.

Note that in the illustrated example, the address decoder 22 is provided with the block selecting lines BLKSEL each corresponding to one memory block BLK. However, this configuration can be appropriately changed. For example, with respect to each two or more memory blocks BLK, a single block selecting line BLKSEL may be provided.

For example, as shown in FIG. 6, the block selecting circuit 23 includes a plurality of block selectors 34 corresponding to the respective memory blocks BLK. These block selectors 34 each include a plurality of block selection transistors 35 that correspond to the word line WL and the selection gate lines (SGD and SGS). The block selection transistor 35 is, for example, a field-effect voltage-resistant transistor. The drain electrode of each block selection transistor 35 is electrically connected to the corresponding word line WL or selection gate line (SGD, SGS). The source electrodes are electrically connected to voltage supply lines 31 via wires CG and the voltage selecting circuit 24. The gate electrodes are commonly connected to the corresponding block selecting line BLKSEL.

Note that the block selecting circuit 23 further includes a plurality of transistors, not shown. These transistors are field-effect voltage-resistant transistors connected between the selection gate lines (SGD and SGS) and voltage supply lines supplied with a ground voltage Vss. These transistors supply the ground voltage V_{SS} to the selection gate lines (SGD and SGS) included in the non-selected memory blocks BLK. Note that the word lines WL included in the non-selected memory blocks BLK are in a floating state.

For example, as shown in FIG. 6, the voltage selecting circuit 24 includes a plurality of voltage selectors 36 that correspond to the word lines WL and selection gate lines (SGD and SGS). These voltage selectors 36 each include a plurality of voltage selection transistors 37. The voltage selection transistors 37 are, for example, field-effect voltage-resistant transistors. The drain terminals of the voltage selection transistors 37 are electrically connected to the corresponding word lines WL or selection gate lines (SGD and SGS) via the wires CG and the block selecting circuit 23. The source terminals are electrically connected to the corresponding voltage supply lines 31. The gate electrodes are connected to the corresponding voltage selecting lines 33.

### Configuration of Sense Amplifier SA

The sense amplifiers SA0 and SA1 (FIG. 5) include respective sense amplifier modules SAM0 and SAM1, and respective cache memories CM0 and CM1. The cache memories CM0 and CM1 respectively include latch circuits XDL0 and XDL1.

Note that in the following description, the sense amplifier modules SAM0 and SAM1 are referred to as the sense amplifier module SAM, the cache memories CM0 and CM1 are referred to as the cache memory CM, and the latch circuits XDL0 and XDL1 are referred to as the latch circuits XDL in some cases.

The sense amplifier module SAM includes, for example, sense circuits corresponding to the respective bit lines BL, and latch circuits connected to the respective sense circuits.

The cache memory CM includes a plurality of latch circuits XDL. The latch circuits XDL are respectively connected to the latch circuits in the sense amplifier modules SAM. For example, user data Dat to be written into the memory cell MC, or user data Dat read from the memory cell MC are stored in the latch circuits XDL.

Note that the user data items Dat included in the latch circuits XDL are transferred to the latch circuit in the sense amplifier module SAM during the write operation. The user data items Dat included in the latch circuits in the sense amplifier modules SAM are transferred to the latch circuits XDL. The user data items Dat included in the latch circuits XDL are transferred to the input and output control circuit I/O via the column decoder COLD, the multiplexer MPX, and the data bus DB during the data output.

### Configuration of Column Decoder COLD

For example, as shown in FIG. 8, the cache memories CM0 and CM1 are respectively connected to the column decoders COLD. Each column decoder COLD includes a multiplexer 41, and a plurality of input and output circuits 42.

The multiplexer 41 decodes the column address CA stored in the address register ADR (FIG. 5), selects the latch circuit XDL corresponding to the column address CA, and connects the selected latch circuit XDL to the input and output circuit 42.

Each input and output circuit 42 includes an input circuit 43, and an output circuit 44.

The input circuit 43 is, for example, a receiver, such as a comparator. The input circuit 43 is connected to the sequencer SQC via a signal line DIN. When the signal of the signal line DIN is activated, the input circuit 43 transitions into the ON state, and outputs data input from the multiplexer MPX to the multiplexer 41. Note that the signal line DIN is commonly connected to the input circuits 43 in the column decoders COLD. The signal line DIN is commonly connected to the column decoders COLD.

The output circuit 44 is, for example, a driver, such as an OCD (Off Chip Driver) circuit. The output circuit 44 is connected to the sequencer SQC via a signal line DOUT. When the signal of the signal line DOUT is activated, the output circuit 44 transitions into the ON state, and outputs data input from the multiplexer 41 to the multiplexer MPX. Note that the signal line DOUT is commonly connected to the input circuits 43 in the column decoders COLD. The signal line DOUT is commonly connected to the column decoders COLD.

### Configuration of Multiplexer MPX

The column decoders COLD are connected to the multiplexer MPX. The multiplexer MPX decodes the plane address stored in the address register ADR (FIG. 5), selects the column decoder COLD corresponding to the plane address, and connects the selected column decoder COLD to the data bus DB. The multiplexer MPX is connected to the sequencer SQC via the signal lines DIN and DOUT.

The multiplexer MPX acquires not only the plane address, but also the column address CA of the defective column in the memory cell array MCA0 stored in a latch circuit BCL0, or the column address CA of the defective column in the memory cell array MCA1 stored in a latch circuit BCL1, and selects an appropriate bit.

### Configuration of Voltage Generation Circuit VG

For example, as shown in FIG. 6, the voltage generation circuit VG (FIG. 5) is connected to the voltage supply lines 31. The voltage generation circuit VG includes, for example, step-down circuit such as regulators, and step-up circuits such as charge pump circuits 32. These step-down circuits and step-up circuits are connected to voltage supply lines supplied with a power source voltage V_{CC} and a ground voltage V_{SS} (FIG. 5). These voltage supply lines are connected to, for example, the pad electrodes P described with reference to FIGS. 2 and 3. For example, according to the control signal from the sequencer SQC, the voltage generation circuit VG generates multiple operation voltages that are to be applied to the bit lines BL, the source line SL, the word lines WL, and the selection gate lines (SGD and SGS) during a read operation, a write operation, and an erase operation for the memory cell array MCA, and outputs the voltages to the voltage supply lines 31 at the same time. The output voltages output from the voltage supply lines 31 are appropriately adjusted according to the control signal from the sequencer SQC.

### Configuration of Sequencer SQC

According to command data Cmd stored in the command register CMR, the sequencer SQC (FIG. 5) outputs internal control signals to the row decoders RD0 and RD1, the sense amplifier modules SAM0 and SAM1, and the voltage generation circuit VG. The sequencer SQC appropriately outputs status data Stt that indicates the state of the memory die MD, to a status register STR. The states of the memory dies MD include ready/busy states of the memory dies MD.

The sequencer SQC generates the ready/busy signal, and outputs it to the terminal RY//BY. For example, the terminal RY//BY is in the “L” state during execution of an operation of supplying the voltage to the memory cell array MCA, such as the read operation, the write operation, and the erase operation, and is in the “H” state in other cases. Note that even when an operation of supplying no voltage to the memory cell array MCA, such as the data output, and status read, is executed, the terminal RY//BY does not transition into “L” state. In a period during which the terminal RY//BY is in the “L” state (busy period), access to the memory die MD is basically prohibited. In a period during which the terminal RY//BY is in the “H” state (ready period), access to the memory die MD is permitted. Note that the terminals RY//BY are implemented by, for example, the pad electrodes P described with reference to FIGS. 2 and 3.

The sequencer SQC includes a feature register FR. The feature register FR is a register that holds feature data Fd. The feature data Fd includes, for example, control parameters for the memory die MD.

### Configuration of Register Circuit RG

The register circuit RG includes an address register ADR, a command register CMR, a status register STR, and a register CDR (FIG. 8).

As shown in FIG. 5, the address register ADR is connected to the input and output control circuit I/O, and stores address data Add input from the input and output control circuit I/O. The address register ADR includes, for example, a plurality of 8-bit register arrays. When an internal operation, such as the read operation, write operation, or erase operation, is executed, each register array holds, for example, address data Add corresponding to the internal operation in execution.

Note that the address data Add includes, for example, the column address CA (FIG. 5), and row address RA (FIG. 5). The row address RA includes, for example, a block address that identifies the memory block BLK (FIG. 6), a page address that identifies the string unit SU and the word line WL, a plane address that identifies the memory cell array MCA (plane), and a chip address that identifies the memory die MD.

The command register CMR is connected to the input and output control circuit I/O, and stores command data Cmd input from the input and output control circuit I/O. The command register CMR includes, for example, at least one set of 8-bit register array. When the command data Cmd is stored in the command register CMR, a control signal is transmitted to the sequencer SQC.

The status registers STR is connected to the input and output control circuit I/O, and stores status data Stt that is to be output to the input and output control circuit I/O. The status register STR includes, for example, a plurality of 8-bit register arrays. When the internal operation, such as the read operation, write operation, or erase operation, is executed, each register array holds, for example, status data Stt corresponding to the internal operation in execution. Each register array holds, for example, ready/busy information that indicates ready or busy states of the memory cell arrays MCA0 and MCA1.

As shown in FIG. 8, the register CDR includes latch circuits BCL0 and BCL1. The latch circuit BCL0 stores the column address CA of a defective column in the memory cell array MCA0. The latch circuit BCL1 stores the column address CA of a defective column in the memory cell array MCA1. The latch circuits BCL0 and BCL1 include, for example, multi-bit register arrays corresponding to the column address CA.

Note that the register CDR is connected to a logic circuit CDRL. The logic circuit CDRL acquires the column addresses CA of the defective columns stored in the latch circuits BCL0 and BCL1 when accessing the sense amplifiers SA0 and SA1, decodes them, and outputs them to the multiplexer MPX. The register CDR includes a data bus having a number of bits that allows connection to one of the latch circuits BCL0 and BCL1. The logic circuit CDRL includes, for example, a data bus having a number of bits that is the same as the number of bits of the column address CA.

### Configuration of Data Output Timing Adjuster TCT

As shown in FIG. 5, the data output timing adjuster TCT is connected to the data bus DB between the cache memories CM0 and CM1 and the input and output control circuit I/O. For example, in a case of sequential execution of data output of the cache memories CM0 and CM1, the data output timing adjuster TCT adjusts the timing of starting data output to the cache memory CM1 in order to start the data output of the cache memory CM1 after completion of data output of the cache memory CM0 without an intervening time period.

### Configuration of Input and Output Control Circuit I/O

The input and output control circuit I/O (FIG. 5) includes data signal input and output terminals DQ0 to DQ7, data strobe signal input and output terminals DQS and /DQS, a shift register, a buffer circuit, a connection change circuit SW, and a phase adjustment circuit PAC.

The data signal input and output terminals DQ0 to DQ7 and the data strobe signal input and output terminals DQS and /DQS are implemented by, for example, the pad electrodes P described with reference to FIGS. 2 and 3. Data input through the data signal input and output terminals DQ0 to DQ7 is input into the cache memory CM from the buffer circuit according to the internal control signal from the logic circuit CTR. The data output through the data signal input and output terminals DQ0 to DQ7 is input into the buffer circuit from the cache memory CM or the status register STR according to the internal control signal from the logic circuit CTR.

Signals input through the data strobe signal input and output terminals DQS and /DQS (for example, the data strobe signal and its complementary signal; may be referred to as “timing signals”) are used when data is input through the data signal input and output terminals DQ0 to DQ7. The data input through the data signal input and output terminals DQ0 to DQ7 is captured into the shift register in the input and output control circuit I/O, at a timing of the rising edge of the voltage of the data strobe signal input and output terminal DQS and of the falling edge of the voltage of the data strobe signal input and output terminal /DQS, and at a timing of the falling edge of the voltage of the data strobe signal input and output terminal DQS and of the rising edge of the voltage of the data strobe signal input and output terminal /DQS.

Signals output through the data strobe signal input and output terminals DQS and /DQS (may be referred to as “timing signals”) are used as reference signals when data is output through the data signal input and output terminals DQ0 to DQ7. The data input through the data signal input and output terminals DQ0 to DQ7 is switched, at a timing of the rising edge of the voltage of the data strobe signal input and output terminal DQS and of the falling edge of the voltage of the data strobe signal input and output terminal /DQS, and at a timing of the falling edge of the voltage of the data strobe signal input and output terminal DQS and of the rising edge of the voltage of the data strobe signal input and output terminal /DQS.

For example, as shown in FIG. 9, the data signal input and output terminals DQ0 to DQ7 and the data strobe signal input and output terminals DQS and /DQS are connected to an input circuit 201 and an output circuit 202. The input circuit 201 is, for example, a receiver, such as a comparator. The output circuit 202 is, for example, a driver, such as an OCD circuit.

The connection change circuit SW (FIG. 5) is a circuit that changes the order of data items input from the outside of the memory dies MD into the data signal input and output terminals DQ0 to DQ7, and captures them into the memory dies MD.

For example, each memory die MD determines whether the memory die MD is included in the forward connection package PKGa (FIG. 4) or included in the reverse connection package PKGb (FIG. 4), based on the feature data Fd stored in the feature register FR.

In an inter-chip copy operation described later, the phase adjustment circuit PAC adjusts the phase of at least one of signals input into the data signal input and output terminals DQ0 to DQ7, signals output from the data signal input and output terminals DQ0 to DQ7, signals input into the data strobe signal input and output terminals DQS and /DQS, and signals output from the data strobe signal input and output terminals DQS and /DQS.

### Configuration of Logic Circuit CTR

The logic circuit CTR (FIG. 5) includes a plurality of control terminals /CE, CA1(CLE), CA0(ALE), CA_clk(/WE), /RE, RE, and /WP, and a logic circuit connected to these control terminals /CE, CA1(CLE), CA0(ALE), CA_clk(/WE), /RE, RE, and /WP. The logic circuit CTR receives an external control signal from the controller die CD through the control terminals /CE, CA1(CLE), CA0(ALE), CA_clk(/WE), /RE, RE, and /WP, and outputs the internal control signal to the input and output control circuit I/O, in response thereto.

For example, as shown in FIG. 9, each of the control terminals /CE, CA1(CLE), CA0(ALE), CA_clk(/WE), /RE, RE, and /WP is connected to the input circuit 201. Each of the control terminals CA1(CLE), CA0(ALE), and /WP is connected not only to the input circuit 201 but also to the output circuit 202. The control terminals /CE, CA1(CLE), CA0(ALE), CA_clk(/WE), /RE, RE, and /WP are implemented by, for example, the pad electrodes P described with reference to FIGS. 2 and 3.

A signal input through the control terminal /CE (for example, a chip enable signal) is used to select the memory dies MD. The memory die MD with “L” being input into the control terminal /CE is in a state where user data Dat, command data Cmd, address data Add, and status data Stt (hereinafter, may be simply referred to as “data”) can be input and output. The memory die MD with “H” being input into the control terminal /CE is in a state where data cannot be input or output. Note that as shown in FIG. 9, the control terminal /CE is connected to the input circuit 201.

A signal input through the control terminal CA1(CLE) (for example, a command latch enable signal) is used for use and the like of the command register CMR.

A signal input through the control terminal CA0(ALE) (for example, an address latch enable signal) is used for use and the like of the address register ADR is used.

In the present embodiment, multi-bit data is input two bits at a time in a time-divided manner through the control terminal CA1(CLE) and the control terminal CA0(ALE). The data is used as, for example, the command data Cmd, address data Add and the like. Note that the multi-bit data input in the time divided manner is obtained by means of signals input through the control terminal CA1(CLE) and the control terminal CA0(ALE), at a timing of the rising edge (for example, switching from the “L” state to the “H” state) of the voltage of the control terminal CA_clk(/WE) and the falling edge (for example, switching from the “H” state to the “L” state) of the voltage of the control terminal CA_clk(/WE), which are described later. Furthermore, in the present embodiment, multi-bit data is output two bits at a time in a time-divided manner through the control terminal CA1(CLE) and the control terminal CA0(ALE). This data is used as, for example, the status data Stt. The functions and the like of the control terminal CA1(CLE) and the control terminal CA0(ALE) are described later.

A signal input through the control terminal CA_clk(/WE) (for example, a write enable signal) is used for inputting and the like of data from the controller die CD to the memory die MD. The functions and the like of the control terminal CA_clk(/WE) are described later.

Signals input through the control terminals /RE and RE (for example, a read enable signal and its complementary signal; may be referred to as “timing signals”) are used to output data through the data signal input and output terminals DQ0 to DQ7. The data output from the data signal input and output terminals DQ0 to DQ7 is switched at a timing of the falling edge of the voltage of the control terminal /RE and of the rising edge of the voltage of the control terminal RE, and at a timing of the rising edge of the voltage of the control terminal /RE and of the falling edge of the voltage of the control terminal RE.

The signal input from the control terminal /WP (for example, a write protect signal) is used to limit inputting of the user data Dat from the controller die CD into the memory dies MD. The signal input from the control terminal /WP may be used as the command data Cmd, address data Add or the like, and the status data Stt may be output from the status register STR through the control terminal /WP.

### Signal Input Method From Controller Die CD Into Memory Dies MD

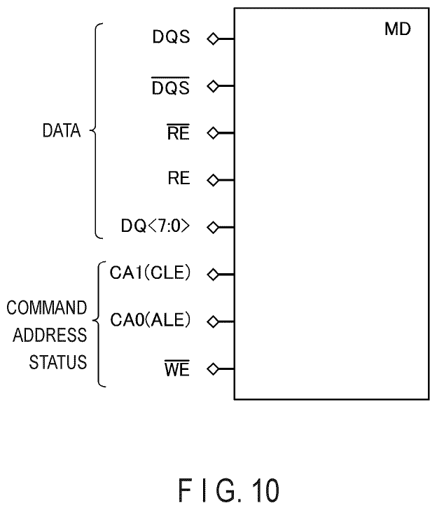

Next, referring to FIGS. 10 to 12, a signal input method from the controller die CD into the memory dies MD in the present embodiment is described.

### Role of Each Terminal

FIG. 10 is a schematic diagram for illustrating roles of signal input and output terminals and control terminals of the memory die MD. Note that in the following description, the data signal input and output terminals DQ0 to DQ7 may be represented as data signal input and output terminals DQ<7:0>.

For example, as shown in FIG. 10, the memory die MD according to the present embodiment uses the data signal input and output terminals DQ<7:0>to input and output the user data Dat, but not to input the command data Cmd and the address data Add and output the status data Stt. The memory die MD according to the present embodiment uses the control terminals CA1(CLE) and CA0(ALE) to input the command data Cmd and the address data Add, and output data, such as the status data Stt.

Parts of signals input and output through the control terminals CA1(CLE) and CA0(ALE) of the memory die MD according to the present embodiment may be referred to as headers. A combination of the headers making up such signals may be referred to as a header set. The header set includes, for example, a 4-bit signal input in a time divided manner into two cycles.

Parts of the command data Cmd, the address data Add, the status data Stt, the feature data Fd and the like that are input and output subsequent to the respective headers may be referred to as bodies. A combination of the bodies making up such data or part of it may be referred to as a body set. The body set includes, for example, 8-bit data input in a time divided manner into four cycles.

A combination of one header set and one body set may be referred to as a frame.

As described above, data of the control terminals CA1(CLE) and CA0(ALE) is captured into a register, not shown, of the logic circuit CTR at a timing of the rising edge and falling edge of the voltage of the control terminal CA_clk(/WE). That is, the data of the control terminals CA1(CLE) and CA0(ALE) is captured into the register, not shown, of the logic circuit CTR according to the toggle of the signal input into the control terminal CA_clk(/WE). In this specification, when the voltage of the control terminal CA_clk(/WE) rises or falls once in one cycle, 2-bit data is input or output via at least one of the control terminals CA1(CLE) and CA0(ALE) in response thereto. For example, when the voltage of the control terminal CA0(ALE) rises and then falls twice in two cycles, 4-bit data is input or output via at least one of the control terminals CA1(CLE) and CA0(ALE) in response thereto.

### Example of Header Set Input

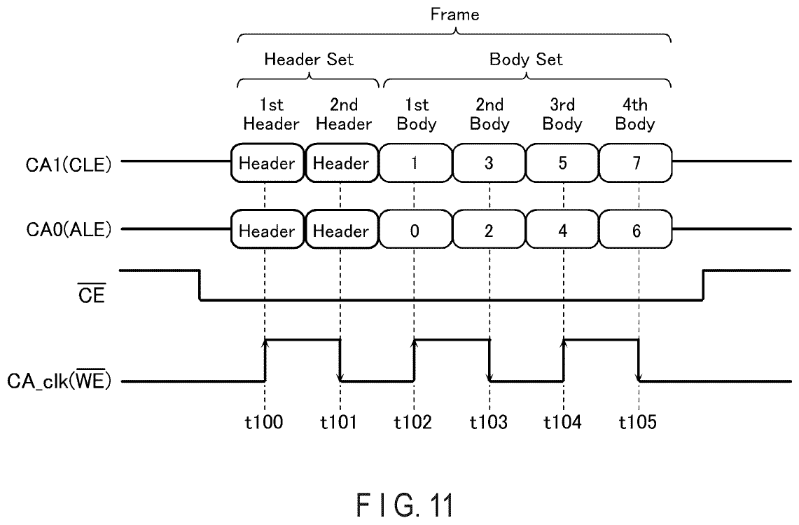

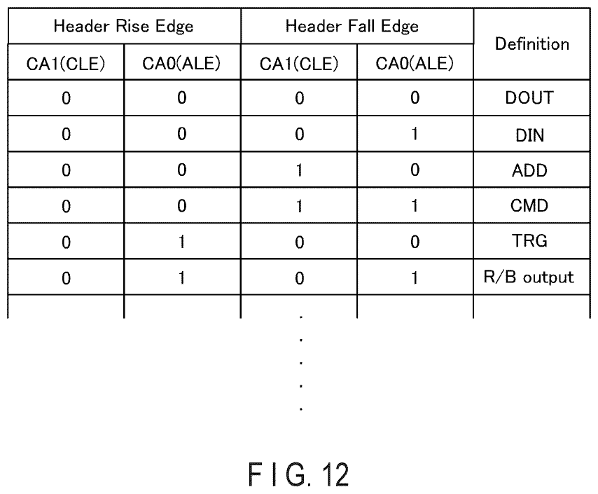

FIG. 11 is a schematic waveform diagram for illustrating the operation of the memory die MD according to the present embodiment. FIG. 12 is a schematic table for illustrating the operation of the memory die MD.

FIG. 11 shows a waveform when the header set is input. In an example in FIG. 11, in a state where a signal in the “L” state is input into the control terminal /CE, a signal in the “L” state and a signal in the “H” state are input into the control terminal CA_clk(/WE) at a substantially constant pace. That is, with the input signal into the control terminal /CE being the “L” state, switching (two toggles) of the input signal where the input signal into the control terminal CA_clk(/WE) once rises from the “L” state to the “H” state and then from the “L” state to the “H” state is repeated.

In the example in FIG. 11, at time t100 and time t101, a 4-bit header set is input in accordance with the rising edge and the falling edge of the signal input into the control terminal CA_clk(/WE). More specifically, at time t100 and time t101, the controller die CD inputs the 4-bit header set shown in FIG. 12 into the memory die MD two bits at a time in a divided manner into two cycles. For example, in a case of issuing an instruction of 8-bit command data Cmd in the body set, the voltages of the control terminals CA1(CLE) and CA0(ALE) are set in accordance with bits “0” and “0”, for inputting of the header in the first cycle. At timing at which the control terminal CA_clk(/WE) is raised from “L” to “H” (rising edge), bits “0” and “0” are captured as the header in the first cycle into a register, not shown, of the logic circuit CTR. For inputting of the header in the second cycle, the voltages of the control terminals CA1(CLE) and CA0(ALE) are set in accordance with the bits “1” and “1”. At timing at which the control terminal CA_clk(/WE) is lowered from “H” to “L” (falling edge), bits “1” and “1” are captured as the header in the second cycle into the register, not shown, of the logic circuit CTR.

In the example in FIG. 11, at time t102 to time t105, an 8-bit body set is input in accordance with the rising edge and the falling edge of the signal input into the control terminal CA_clk(/WE). More specifically, at time t102 to time t105, the controller die CD inputs, into the memory die MD, the 8-bit body set according to 4-bit header set (entry condition) two bits at a time in a divided manner into four cycles. For example, the 8-bit command data Cmd is assumed as bits “0” to “7”. First, for inputting of the body (data) in the first cycle, the voltages of the control terminals CA1(CLE) and CA0(ALE) are set in accordance with the bits “1” and “0”. At timing when the control terminal CA_clk(/WE) is raised from “L” to “H” (rising edge), the body in the first cycle is captured. For inputting of the body (data) in the second cycle, the voltages of the control terminals CA1(CLE) and CA0(ALE) are set in accordance with the bits “3” and “2”. At timing when the control terminal CA_clk(/WE) is lowered from “H” to “L” (falling edge), the body in the second cycle is captured. Likewise, also for inputting of the body in the third and fourth cycles, the voltages of the control terminals CA1(CLE) and CA0(ALE) are set in accordance with the bits “5” and “4”, and bits “7” and “6”. At a timing when the control terminal CA_clk(/WE) is raised (rising edge) and timing when it is lowered (falling edge), the body in the third and fourth cycles is captured.

Note that in the above description, the operation in the case of “CMD” in the table shown in FIG. 12, i.e., the operation in the case where the command data Cmd is input as the body set is given as an example. In this case, as described above, 4-bit data “0”, “0”, “1”, and “1” is input as the header set. However, this is only an example.

For example, in a case where the command data Cmd is input as the body set, 4-bit data “0”, “0”, “1”, and “0” is input as the header set, in a manner similar to the case of “ADD” in the table shown in FIG. 12. For example, in a case where data is output as the body set, 4-bit data “0”, “0”, “0”, and “0” is input as the header set, in a manner similar to the case of “DOUT” in the table shown in FIG. 12. The header set corresponding to “DOUT” is input when the status data Stt or the feature data Fd is output, for example. For example, in a case where data is input as the body set, 4-bit data “0”, “0”, “0”, and “1” is input as the header set, in a manner similar to the case of “DIN” in the table shown in FIG. 12. The header set corresponding to “DIN” is input when the feature data Fd is input, for example. For example, when the ready/busy state is output, 4-bit data “0”, “1”, “0”, and “1” is input as the header set in a manner similar to the case of “R/B output” in the table shown in FIG. 12.

Note that Header Rise Edge shown in FIG. 12 indicates a 2-bit first header input in accordance with the rising edge of the header in the first cycle, i.e., the signal input into the control terminal CA_clk(/WE). Header Fall Edge shown in FIG. 12 indicates a 2-bit second header input in accordance with the falling edge of the header in the second cycle, i.e., the signal input into the control terminal CA_clk(/WE).

### Operation

Next, the operation of the memory die MD is described.

The memory die MD is configured to be capable of executing the read operation. The read operation is an operation of reading the user data Dat from the memory cell array MCA by the sense amplifier module SAM (FIG. 5), and transferring the read user data Dat to the latch circuit XDL.

The memory die MD is configured to be capable of executing data output. The data output of the user data Dat is an operation of outputting the user data Dat included in the latch circuits XDL, to the controller die CD. In the data output of the user data Dat, the user data Dat included in the latch circuit XDL is output to the controller die CD via the column decoder COLD, the multiplexer MPX, the data bus DB, and the input and output control circuit I/O described with reference to FIG. 8.

The memory die MD is configured to be capable of executing the write operation. The write operation is an operation of writing, into the memory cell array MCA, the user data Dat input from the controller die CD. In the write operation, the user data Dat input from the controller die CD is transferred to the sense amplifier SA via the input and output control circuit I/O, the data bus DB, the multiplexer MPX, and the column decoder COLD. The user data Dat transferred to the sense amplifier SA is written into the memory cell array MCA.

### Read Operation

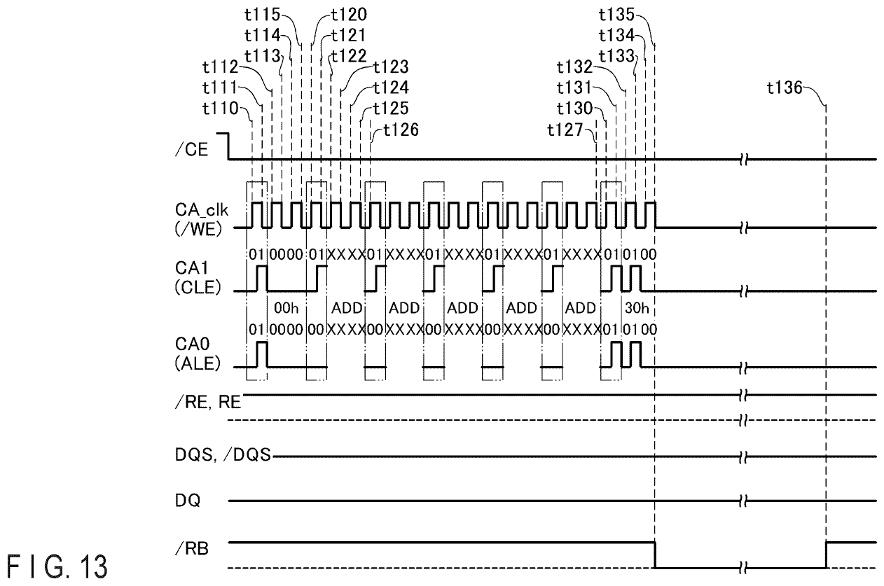

FIG. 13 is a schematic waveform diagram for illustrating the read operation, and shows input and output signals between the controller die CD and the memory die MD.

Before time t110 in FIG. 13, the voltage of the control terminal /CE is lowered from “H” to “L”.

Subsequently, from time t110 to time t135, the controller die CD inputs the command set of the read operation into the memory die MD. That is, the controller die CD inputs the command data Cmd for an instruction of the read operation into the memory die MD from time t110 to time t115, inputs the address data Add for designating the memory cells MC serving as the target of the read operation into the memory die MD from time t120 to time t127, and inputs the command data Cmd for starting the read operation into the memory die MD from time t130 to time t135.

More specifically, at times t110 and t111, the controller die CD inputs, into the memory dies MD, the header set that includes the header indicating bits “0” and “0” in the first cycle, and the header indicating bits “1” and “1” in the second cycle, via the control terminals CA1(CLE) and CA0(ALE). As shown in FIG. 12, the header set is a header set that indicates an instruction of inputting the command data Cmd, and is input at (timing of) the rising edge and the falling edge of the signal input into the control terminal CA_clk(/WE). In other words, at times t110 and t111, a portion corresponding to the header set (4-bit information) in the frame corresponding to the command data Cmd included in the command set of the read operation is input into the memory die MD according to two toggles of the signal input into the control terminal CA_clk(/WE).

From time t112 to time t115, the controller die CD inputs command data 00h as the body set into the memory die MD via the control terminals CA1(CLE) and CA0(ALE). The command data “00h” is the command data Cmd for an instruction of the read operation. In other words, at times t112 and t115, a portion corresponding to the body set (8-bit information) in the frame corresponding to the command data Cmd included in the command set of the read operation is input into the memory die MD according to four toggles of the signal input into the control terminal CA_clk(/WE).

At times t120 and t121, the controller die CD inputs, into the memory die MD, the header set that includes the header indicating bits “0” and “0” in the first cycle, and the header indicating bits “1” and “0” in the second cycle, via the control terminals CA1(CLE) and CA0(ALE). As shown in FIG. 12, the header set is a header set that indicates an instruction of inputting the address data Add, and is input at the rising edge and the falling edge of the signal input into the control terminal CA_clk(/WE). In other words, at times t120 and t121, a portion corresponding to the header set (4-bit information) in the frame corresponding to the address data Add included in the command set of the read operation is input into the memory die MD according to two toggles of the signal input into the control terminal CA_clk(/WE).

From time t122 to time t125, the controller die CD inputs the address data Add as the body set into the memory die MD via the control terminals CA1(CLE) and CA0(ALE). This address data Add is data for designating the memory cells MC serving as the target of the read operation. In other words, at times t122 and t125, a portion corresponding to the body set (8-bit information) in the frame corresponding to the address data Add included in the command set of the read operation is input into the memory die MD according to four toggles of the signal input into the control terminal CA_clk(/WE).

From time t126 to time t127, an operation similar to the operation from time t120 to time t125 is executed multiple times (four times in the illustrated example), and a plurality of (four in the illustrated example) frames are input. Accordingly, from time t120 to time t127, address data Add of 8-bit×5 times=40 bits is input into the memory die MD.

At times t130 and t131, the controller die CD inputs, into the memory die MD, the header set that includes the header indicating bits “0” and “0” in the first cycle, and the header indicating bits “1” and “1” in the second cycle, via the control terminals CA1(CLE) and CA0(ALE).

From time t132 to time t135, the controller die CD inputs command data 30h as the body set into the memory die MD via the control terminals CA1(CLE) and CA0(ALE). The command data “30h” is the command data Cmd for an instruction of starting the read operation.

When inputting of the command data “30h” is executed at time t135, the read operation is started, and the voltage of the terminals RY//BY falls from “H” to “L”.

In the illustrated example, the read operation ends at time t136, the voltage of the terminals RY//BY rises from “L” to “H”.

### Data Output

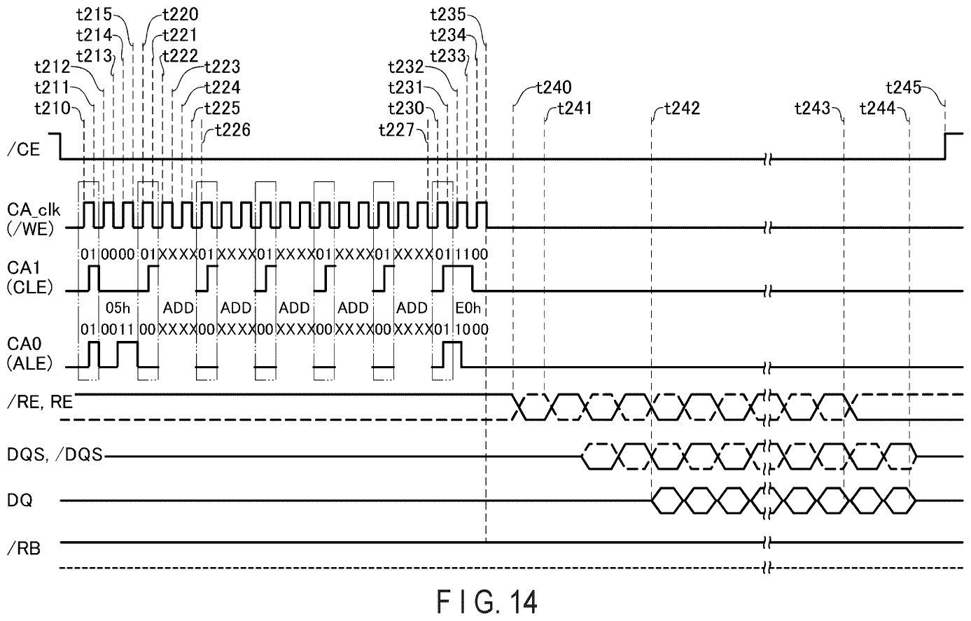

FIG. 14 is a schematic waveform diagram for illustrating the data output, and shows input and output signals between the controller die CD and the memory die MD.

Before time t210 in FIG. 14, the voltage of the control terminal /CE falls from “H” to “L”.

Subsequently, from time t210 to time t235, the controller die CD inputs the command set of the data output into the memory die MD. That is, the controller die CD inputs the command data Cmd for an instruction of the data output into the memory die MD from time t210 to time t215, inputs the address data Add for designating the memory cells MC serving as the target of the data output into the memory die MD from time t220 to time t227, and inputs the command data Cmd for starting the data output into the memory die MD from time t230 to time t235.

The operation of data output from time t210 to time t235 is executed basically similarly to the operation of read operation from time t110 to time t135.

Note that from time t212 to time t215, the controller die CD inputs command data 05h, instead of command data 00h, into the memory die MD. The command data “05h” is the command data Cmd for an instruction of data output.

From time t230 to time t235, the controller die CD inputs command data E0h, instead of command data 30h, into the memory die MD. The command data “E0h” is the command data Cmd for an instruction of starting data output.

From time t240 to time t243, the controller die CD switches the input signals into the control terminals /RE and RE (toggles the input signals into the control terminals /RE and RE), and designates timing at which the user data Dat is output. More specifically, at time t240, the controller die CD switches the input signal into the control terminal /RE from “H” to “L”, and switches the input signal into the control terminal RE from “L” to “H”. More specifically, at time t241, the controller die CD switches the input signal into the control terminal /RE from “L” to “H”, and switches the input signal into the control terminal RE from “H” to “L”. Subsequently, switching (toggle) is repeated. Accordingly, at time t242, outputting of the user data Dat is started, and the user data Dat stored in the latch circuit XDL is output via the data signal input and output terminals DQ0 to DQ7. Note that the signals of the data strobe signal input and output terminals DQS and /DQS rise or falls at timing when data is output to the data signal input and output terminals DQ0 to DQ7. Consequently, even in a case where “0” is continuously output from the data signal input and output terminals DQ0 to DQ7, and a case where “1” is continuously output, delimitation of data can be determined.

At the end of switching of the input signals into the control terminals /RE and RE at time t243, outputting of the user data Dat also ends at time t244.

In the illustrated example, at time t245, the voltage of the control terminal /CE rises from “L” to “H”.

### Write Operation

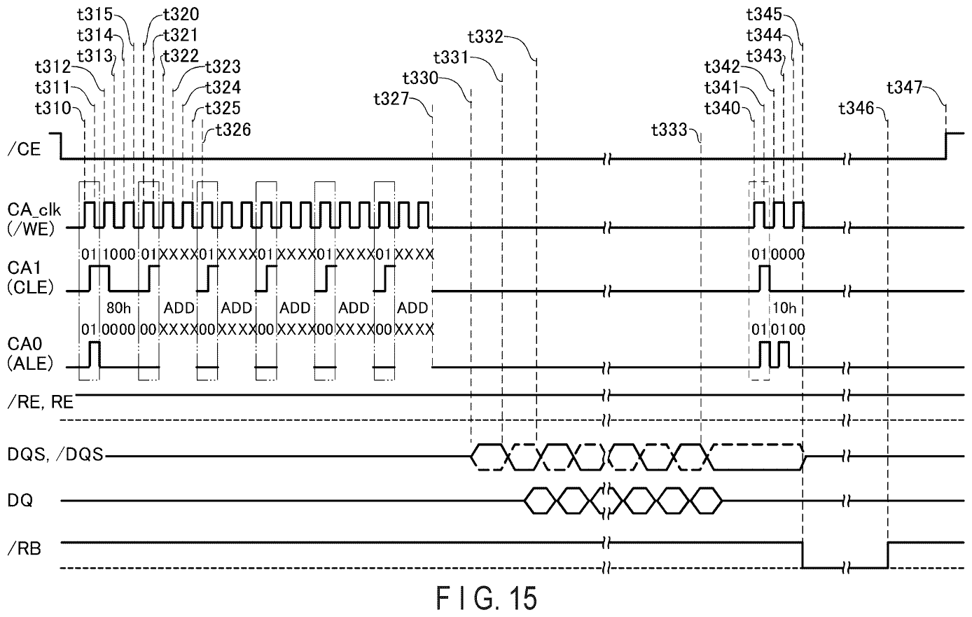

FIG. 15 is a schematic waveform diagram for illustrating the write operation, and shows input and output signals between the controller die CD and the memory dies MD.

Before time t310 in FIG. 15, the voltage of the control terminal /CE falls from “H” to “L”.

Subsequently, from time t310 to time t345, the controller die CD inputs the command set of the write operation into the memory die MD. That is, the controller die CD inputs the command data Cmd for an instruction of the write operation into the memory die MD from time t310 to time t315, inputs the address data Add for designating the memory cells MC serving as the target of the write operation into the memory die MD from time t320 to time t327, inputs, into the memory die MD, the user data Dat to be written into the memory cells MC, from time t330 to time t333, and inputs the command data Cmd for starting the write operation into the memory die MD from time t340 to time t345.

More specifically, at times t310 and t311, the controller die CD inputs, into the memory die MD, the header set that includes the header indicating bits “0” and “0” in the first cycle, and the header indicating bits “1” and “1” in the second cycle, via the control terminals CA1(CLE) and CA0(ALE).

From time t312 to time t315, the controller die CD inputs command data 80h as the body set into the memory die MD via the control terminals CA1(CLE) and CA0(ALE). The command data “80h” is the command data Cmd for an instruction of the write operation.

At times t320 and t321, the controller die CD inputs, into the memory die MD, the header set that includes the header indicating bits “0” and “0” in the first cycle, and the header indicating bits “1” and “0” in the second cycle, via the control terminals CA1(CLE) and CA0(ALE).

From time t322 to time t325, the controller die CD inputs the address data Add as the body set into the memory die MD via the control terminals CA1(CLE) and CA0(ALE). This address data Add is data for designating the memory cells MC serving as the target of the write operation.

From time t326 to time t327, an operation similar to the operation from time t320 to time t325 is executed multiple times (four times in the illustrated example), and a plurality of (four in the illustrated example) frames are input. Accordingly, from time t320 to time t327, address data Add of 8-bit×5 times=40 bits is input into the memory die MD.

From time t330 to time t333, the controller die CD switches the input signals into the data strobe signal input and output terminals DQS and /DQS (toggles the input signals into the data strobe signal input and output terminals DQS and /DQS), and designates timing at which the user data Dat is input. More specifically, at time t330, the controller die CD switches the input signal into the data strobe signal input and output terminal DQS to “H”, and switches the input signal into the data strobe signal input and output terminal /DQS to “L”. At time t331, the controller die CD switches the input signal into the data strobe signal input and output terminal DQS from “H” to “L”, and switches the input signal into the data strobe signal input and output terminal /DQS from “L” to “H”. Furthermore, at time t332, in a state where 8-bit data constituting the user data Dat is input into the data signal input and output terminals DQ0 to DQ7, the input signal into the data strobe signal input and output terminal DQS is switched from “L” to “H”, and the input signal into the data strobe signal input and output terminal /DQS is switched from “H” to “L”. Subsequently, while the 8-bit data constituting the user data Dat is input into the data signal input and output terminals DQ0 to DQ7, switching (toggle) of the input signals into the data strobe signal input and output terminals DQS and /DQS is repeated.

At times t340 and t341, the controller die CD inputs, into the memory die MD, the header set that includes the header indicating bits “0” and “0” in the first cycle, and the header indicating bits “1” and “1” in the second cycle, via the control terminals CA1(CLE) and CA0(ALE).

From time t342 to time t345, the controller die CD inputs command data 10h as the body set into the memory die MD via the control terminals CA1(CLE) and CA0(ALE). The command data “10h” is the command data Cmd for an instruction of starting the write operation.

When inputting of the command data “10h” is executed at time t345, the write operation is started, and the voltage of the terminals RY//BY falls from “H” to “L”.

In the illustrated example, the write operation ends at time t346, the voltage of the terminals RY//BY rises from “L” to “H”.

In the illustrated example, at time t347, the voltage of the control terminal /CE rises from “L” to “H”.

### Inter-Chip Copy Operation

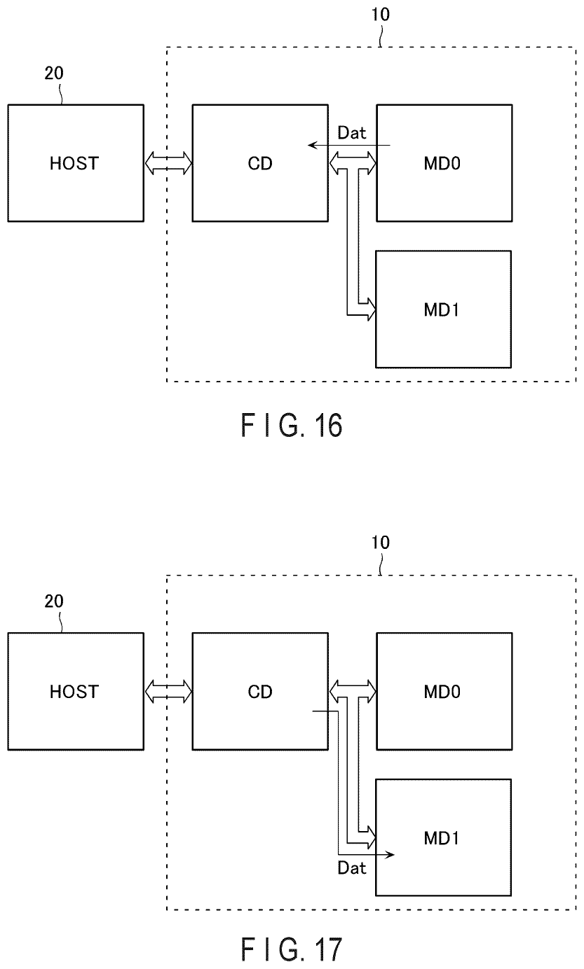

Next, referring to FIGS. 16 to 18, an inter-chip copy operation is described. FIGS. 16 to 18 are schematic block diagrams for illustrating the inter-chip copy operation.

In a case of copying the user data Dat written in the memory die MD in the memory system 10 (memory die MD0 in the illustrated example) to another memory die MD in the memory system 10 (memory die MD1 in the illustrated example), for example, it is conceivable that first, the read operation and the data output described above are executed, and as shown in FIG. 16, the user data Dat is transferred from the memory die MD0 to the controller die CD. It is conceivable that the write operation described above is subsequently executed, and as shown in FIG. 17, the read user data Dat is transferred to the memory die MD1.

Here, while the operation corresponding to time t240 to time t244 described with reference to FIG. 14 (the operation of transferring the user data Dat from the memory die MD to the controller die CD) is in execution, the data bus between the controller die CD and the memory die MD is occupied. Consequently, at this timing, the operation corresponding to time t330 to time t333 described with reference to FIG. 15 (the operation of transferring the user data Dat from the controller die CD to the memory die MD) cannot be executed.

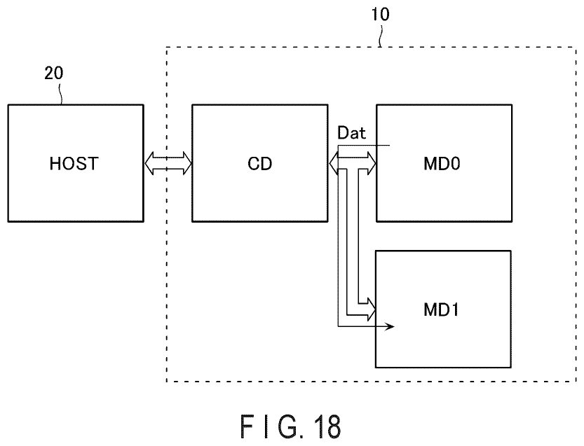

The memory system 10 according to the present embodiment is configured to be capable of executing the inter-chip copy operation. As shown in FIG. 18, in the inter-chip copy operation, the user data Dat is directly transferred from the memory die MD0 to the memory die MD1 without intervention of the controller die CD. In this case, the operation corresponding to time t240 to time t244 described with reference to FIG. 14, and the operation corresponding to time t330 to time t333 described with reference to FIG. 15 are executed in parallel.

According to such a method, time required to copy the user data Dat between the memory dies MD0 and MD1 can be greatly reduced.

Note that in the inter-chip copy operation, the user data Dat output from the memory die MD0 is not input into the controller die CD. The controller die CD does not output the user data Dat that is to be input into the memory die MD1.

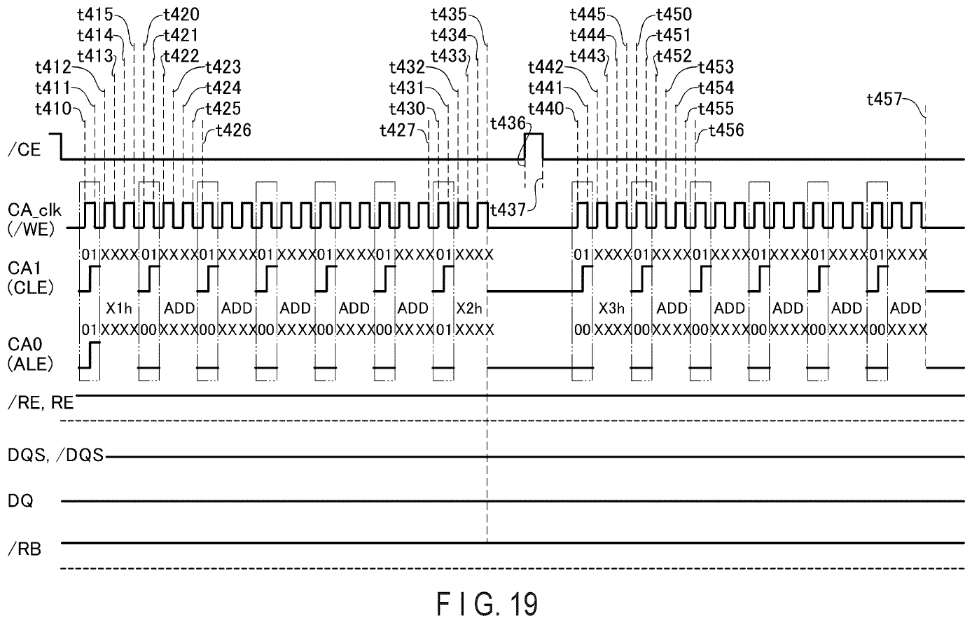

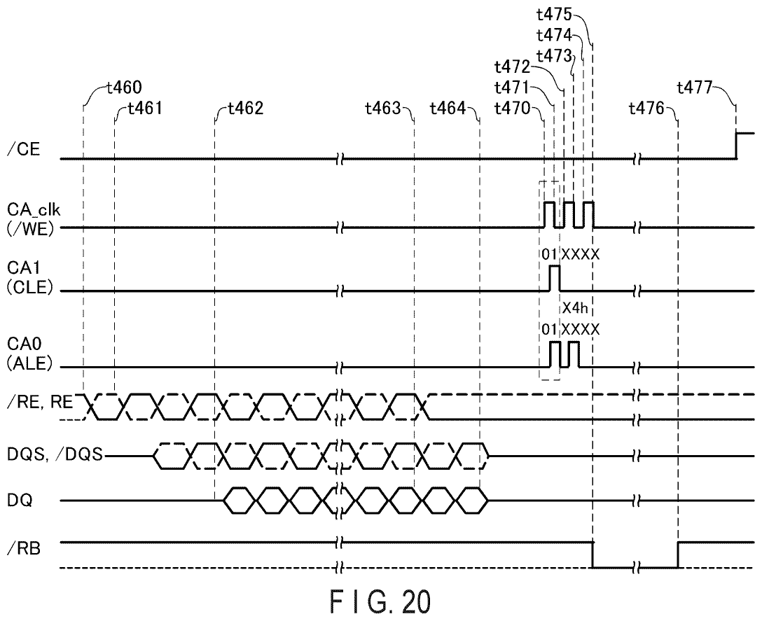

Next, referring to FIGS. 19 and 20, the inter-chip copy operation is described in more detail.

FIGS. 19 and 20 are schematic waveform diagrams for illustrating the inter-chip copy operation. FIG. 20 shows the continuation of the waveform diagram of FIG. 19.

Before time t410 in FIG. 19, the voltage of the control terminal /CE falls from “H” to “L”.

Subsequently, from time t410 to time t435, the controller die CD inputs a first command set corresponding to the inter-chip copy operation, into the memory die MD0 that executes the operation corresponding to data output. That is, the controller die CD inputs the command data Cmd for an instruction of executing the inter-chip copy operation into the memory die MD0 from time t410 to time t415, inputs the address data Add for designating the memory cells MC serving as the target of the inter-chip copy operation into the memory die MD0 from time t420 to time t427, and inputs the command data Cmd for designating the inter-chip copy operation into the memory die MD0 from time t430 to time t435.

The operation of inter-chip copy operation from time t410 to time t435 is executed basically similarly to the operation of read operation from time t110 to time t135.

Note that from time t412 to time t415, the controller die CD inputs command data X1h, instead of command data 00h, into the memory die MD0. The command data X1h is command data Cmd for designating the inter-chip copy operation.

From time t430 to time t435, the controller die CD inputs command data X2h, instead of command data 30h, into the memory die MD0. The command data X2h is command data Cmd for designating the inter-chip copy operation.

Note that from time t430 to time t435, the command data X2h input into the memory die MD0 is different from the command data X1h input into the memory die MD0 from time t412 to time t415.

In the illustrated example, at the end of input of the command set, the voltage of the control terminal /CE rises from “L” to “H” at time t436. At time t437, the voltage of the control terminal /CE falls from “H” to “L”.

Subsequently, from time t440 to time t475, the controller die CD inputs a second command set corresponding to the inter-chip copy operation into the memory die MD1 that executes an operation corresponding to the write operation. That is, the controller die CD inputs the command data Cmd for an instruction of the inter-chip copy operation into the memory die MD1 from time t440 to time t445, inputs the address data Add for designating the memory cells MC serving as the target of the inter-chip copy operation from time t450 to time t457, inputs, into the memory die MD, the user data Dat to be written into the memory cells MC, from time t460 to time t464, and inputs the command data Cmd for starting the inter-chip copy operation, into the memory die MD from time t470 to time t475.

The operation of inter-chip copy operation from time t440 to time t457 is executed basically similarly to the operation in the write operation from time t310 to time t327.

Note that from time t442 to time t445, the controller die CD inputs command data X3h, instead of command data 00h, into the memory die MD1. The command data X3h is command data Cmd for an instruction of the inter-chip copy operation.

Note that the command data X3h input into the memory die MD0 from time t442 to time t445 is different from the command data X1h input into the memory die MD0 from time t412 to time t415 and from the command data X2h input into the memory die MD0 from time t430 to time t435.

From time t460 to time t463, the controller die CD switches the input signals for the control terminals /RE and RE (toggles the input signals for the control terminals /RE and RE), and designates timing at which the user data Dat is output from the memory die MD0, and timing at which the user data Dat is input into the memory die MD1.

The operation of the memory die MD0 in the inter-chip copy operation from time t460 to time t463 is executed basically similarly to the operation of data output from time t240 to time t243 (FIG. 14). That is, when the controller die CD toggles the input signals for the control terminals /RE and RE, the memory die MD0 outputs data to the data signal input and output terminals DQ0 to DQ7 at timing when the input signals into the control terminals /RE and RE are switched. At this timing, the signals of data strobe signal input and output terminals DQS and /DQS are switched. Note that the user data Dat output from the memory die MD0 is not input into the controller die CD.

The operation of the memory die MD1 in the inter-chip copy operation from time t460 to time t463 is executed basically similarly to the operation of the write operation from time t330 to time t333 (FIG. 15). Note that in the inter-chip copy operation, the signals of the data strobe signal input and output terminals DQS and /DQS are output from the memory die MD0 instead of the controller die CD. Consequently, the user data Dat is input into the memory die MD1 at timing based on the signals of the data strobe signal input and output terminals DQS and /DQS output from the memory die MD0.

At the end of switching of the input signals into the control terminals /RE and RE at time t463, transfer of the user data Dat also ends at time t464.

The operation of inter-chip copy operation from time t470 to time t477 is executed basically similarly to the operation in the write operation from time t340 to time t347.

Note that from time t472 to time t475, the controller die CD inputs command data X4h, instead of command data 10h, into the memory die MD1. The command data X4h is command data Cmd for designating start of the inter-chip copy operation.

Note that the command data X4h input into the memory die MD1 from time t472 to time t475 is different from the command data X1h input into the memory die MD0 from time t412 to time t415, from the command data X2h input into the memory die MD0 from time t430 to time t435, and from the command data X3h input into the memory die MD0 from time t442 to time t445.

### Role of Phase Adjustment Circuit PAC in Inter-Chip Copy Operation

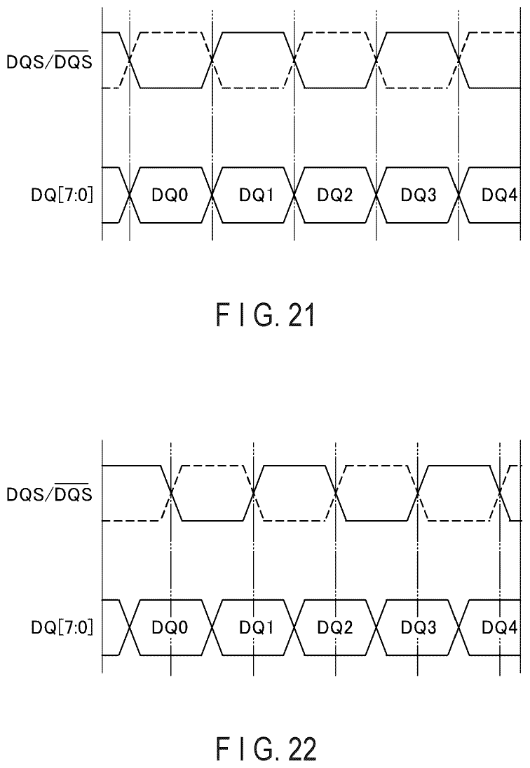

Next, referring to FIGS. 21 to 24, the role of the phase adjustment circuit PAC in the inter-chip copy operation is described. FIGS. 21 to 24 are schematic waveform diagrams for illustrating the role of the phase adjustment circuit PAC in the inter-chip copy operation.

From time t242 to time t244 in the data output described with reference to FIG. 14, as shown in FIG. 21, the signals of the data strobe signal input and output terminals DQS and /DQS rise or fall at a timing when data is output to the data signal input and output terminals DQ0 to DQ7. That is, the phases of the signals output from the data strobe signal input and output terminals DQS and /DQS coincide with the phases of the signals output from the data signal input and output terminals DQ0 to DQ7.

On the other hand, from time t332 to time t333 in the write operation described with reference to FIG. 15, as shown in FIG. 22, in a state where 8-bit data constituting the user data Dat is input into the data signal input and output terminals DQ0 to DQ7, the controller die CD raises the input signals that are the signals of the data strobe signal input and output terminals DQS and /DQS from “L” to “H”, or lowers the signals from “H” to “L”. That is, the phases of the signals output from the data strobe signal input and output terminals DQS and /DQS do not coincide with the phases of the signals output from the data signal input and output terminals DQ0 to DQ7. The phases of these signals are delayed by, for example, a half wavelength.

The input and output control circuit I/O (FIG. 5) is configured assuming such an operation. Consequently, in the inter-chip copy operation, it is desired to preferably adjust the relationship between the phases of the signals output from the data strobe signal input and output terminals DQS and /DQS, and the phases of the signals output from the data signal input and output terminals DQ0 to DQ7.

As described with reference to FIG. 5, the memory die MD according to the present embodiment includes the phase adjustment circuit PAC.

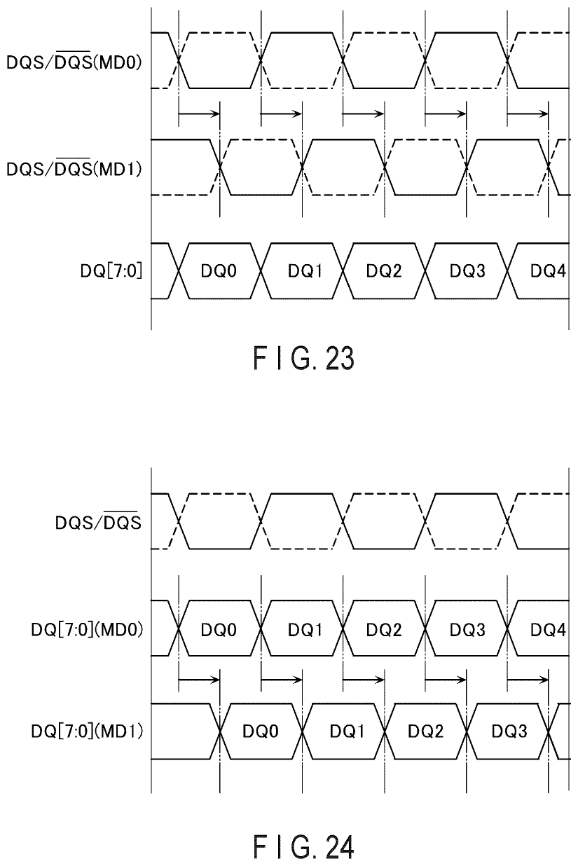

For example, as shown in FIG. 23, the phase adjustment circuit PAC may delay, by a half wavelength, the signals of the data strobe signal input and output terminals DQS and /DQS output from the memory die MD0, and input the signals into the memory die MD1. In this case, the phases of the signals of the data strobe signal input and output terminals DQS and /DQS can be delayed by a half wavelength by the phase adjustment circuit PAC mounted on the memory die MD0. In this case, on the data bus between the memory dies MD0 and MD1, the phases of the signals of the data strobe signal input and output terminals DQS and /DQS, and the phases of the signals of the data signal input and output terminals DQ0 to DQ7 deviate from each other by a half wavelength.

Note that the phases of the signals of the data strobe signal input and output terminals DQS and /DQS may be delayed by a half wavelength by the phase adjustment circuit PAC mounted on the memory die MD1. In this case, on the data bus between the memory dies MD0 and MD1, the phases of the signals of the data strobe signal input and output terminals DQS and /DQS, and the phases of the signals of the data signal input and output terminals DQ0 to DQ7 coincide with each other.

The phases of the signals of the data strobe signal input and output terminals DQS and /DQS may be delayed by a ¼ wavelength each by the phase adjustment circuits PAC mounted on the memory dies MD0 and MD1. In this case, on the data bus between the memory dies MD0 and MD1, the phases of the signals of the data strobe signal input and output terminals DQS and /DQS are delayed only by a ¼ wavelength from the phases of the signals of the data signal input and output terminals DQ0 to DQ7.

For example, as shown in FIG. 24, the phase adjustment circuit PAC may delay, by a half wavelength, the signals of the data signal input and output terminals DQ0 to DQ7 output from the memory die MD0, and input the signals into the memory die MD1. In this case, the phases of the signals of the data signal input and output terminals DQ0 to DQ7 can be delayed by a half wavelength by the phase adjustment circuit PAC mounted on the memory die MD0. In this case, on the data bus between the memory dies MD0 and MD1, the phases of the signals of the data strobe signal input and output terminals DQS and /DQS, and the phases of the signals of the data signal input and output terminals DQ0 to DQ7 deviate from each other by a half wavelength.

Note that the phases of the signals of the data signal input and output terminals DQ0 to DQ7 may be delayed by a half wavelength by the phase adjustment circuit PAC mounted on the memory die MD1. In this case, on the data bus between the memory dies MD0 and MD1, the phases of the signals of the data strobe signal input and output terminals DQS and /DQS, and the phases of the signals of the data signal input and output terminals DQ0 to DQ7 coincide with each other.

The phases of the signals of the data signal input and output terminals DQ0 to DQ7 may be delayed by a ¼ wavelength each by the phase adjustment circuits PAC mounted on the memory dies MD0 and MD1. In this case, on the data bus between the memory dies MD0 and MD1, the phases of the signals of the data signal input and output terminals DQ0 to DQ7 are delayed only by a ¼ wavelength from the phases of the signals of the data strobe signal input and output terminals DQS and /DQS.

### Second Embodiment

In the first embodiment, the memory system 10 that can execute the inter-chip copy operation of copying the user data Dat from one of the two memory dies MD to the other is described. In the second embodiment, a memory die MD2 that can execute an inter-plane copy operation of copying the user data Dat from one of two memory cell arrays MCA to the other is described.

### Configuration

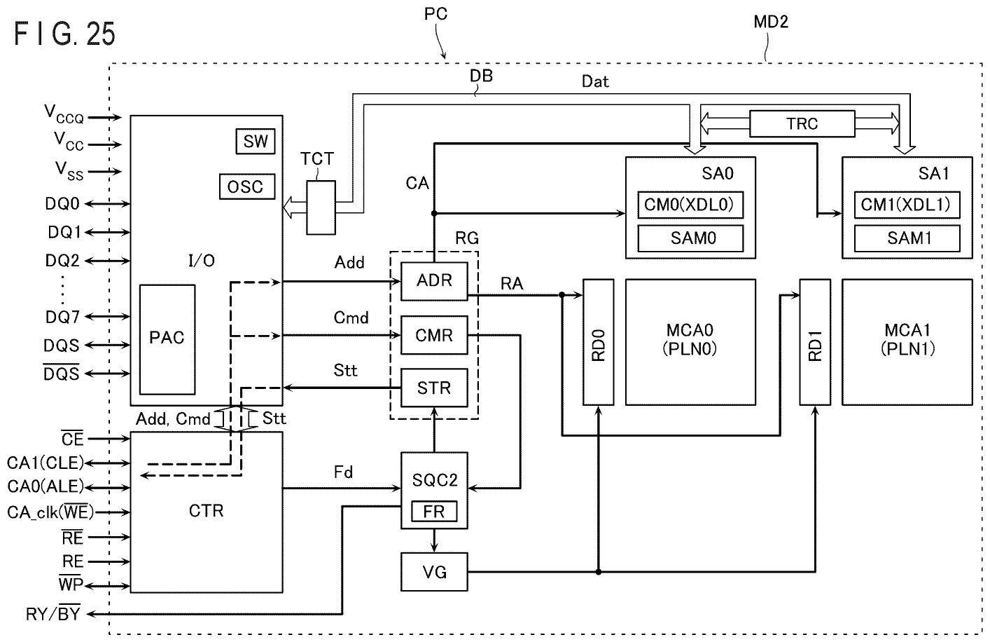

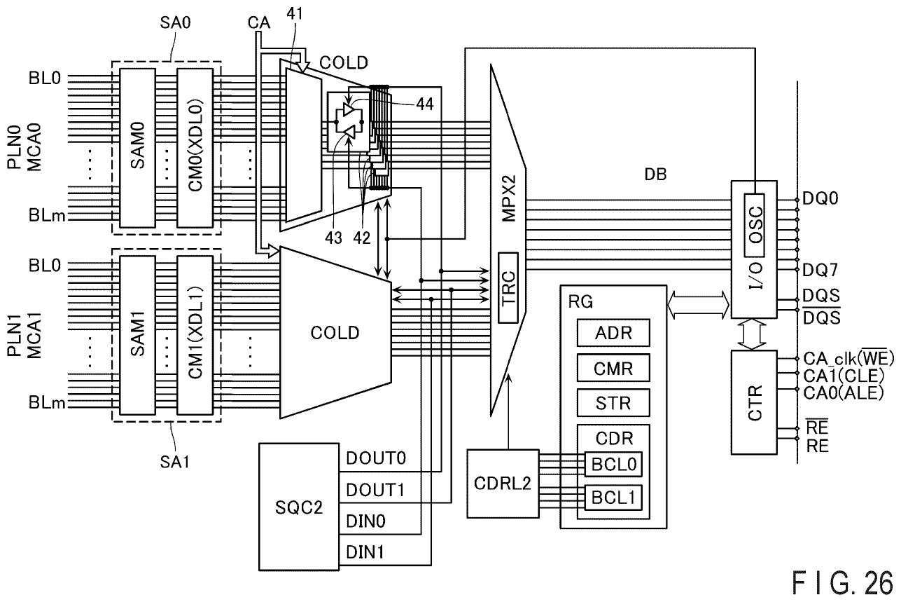

FIG. 25 is a schematic block diagram showing the configuration of the memory die MD2 according to the second embodiment. FIG. 26 is a schematic circuit diagram showing the configuration of part of the memory die MD2. For the sake of description, part of the configuration is omitted in FIGS. 25 and 26.

Note that in the following description, components similar to those in the first embodiment are assigned the same symbols, and description of them is omitted.

The memory die MD2 according to the second embodiment is configured basically similarly to the memory die MD according to the first embodiment. Note that as shown in FIG. 26, the memory die MD2 according to the second embodiment includes a multiplexer MPX2 instead of the multiplexer MPX. The memory die MD2 according to the second embodiment includes a sequencer SQC2 instead of the sequencer SQC. The input and output control circuit I/O of the memory die MD2 includes an oscillation circuit OSC (timing signal generation circuit). The memory die MD2 according to the second embodiment includes a logic circuit CDRL2 instead of the logic circuit CDRL.

The multiplexer MPX2 is configured basically similarly to the multiplexer MPX. Note that the multiplexer MPX2 includes a transfer circuit TRC. The transfer circuit TRC is a bidirectional buffer that can input the user data Dat output from a certain memory cell array MCA (the memory cell array MCA0 in the illustrated example) in the memory die MD2, into another memory cell array MCA (memory cell array MCA1 in the illustrated example) in the memory die MD2. When the user data Dat output from the memory cell array MCA0 is input into the memory cell array MCA1, the transfer circuit TRC is allowed not to output the user data Dat to the data bus DB.

The sequencer SQC2 is configured similarly to the sequencer SQC.

Note that as described with reference to FIG. 8, the sequencer SQC includes signal lines DIN and DOUT. The signal line DIN is commonly connected to the column decoders COLD. The signal line DOUT is commonly connected to the column decoders COLD.

On the other hand, as shown in FIG. 26, the sequencer SQC2 includes signal lines DIN0, DIN1, DOUT0, and DOUT1. The signal lines DIN0 and DOUT0 are connected to the column decoder COLD corresponding to the memory cell array MCA0, but are not connected to the column decoder COLD corresponding to the memory cell array MCA1. The signal lines DIN1 and DOUT1 are connected to the column decoder COLD corresponding to the memory cell array MCA1, but are not connected to the column decoder COLD corresponding to the memory cell array MCA0.

When the user data Dat is copied from the memory cell array MCA0 to the memory cell array MCA1 during execution of the inter-plane copy operation, the signal lines DOUT0 and DIN1 are activated but the signal lines DOUT1 and DIN0 are not activated. When the user data Dat is copied from the memory cell array MCA1 to the memory cell array MCA0, the signal lines DOUT1 and DIN0 are activated but the signal lines DOUT0 and DIN1 are not activated.

The oscillation circuit OSC is commonly connected to the column decoders COLD. When the user data Dat is copied from the memory cell array MCA0 to the memory cell array MCA1 during execution of the inter-plane copy operation, the column decoder COLD corresponding to the memory cell array MCA0 outputs the user data Dat and the timing signal according to the timing signal output from the oscillation circuit OSC. The user data Dat is input into the column decoder COLD corresponding to the memory cell array MCA1, according to the timing signal output from the column decoder COLD corresponding to the memory cell array MCA0.

The logic circuit CDRL2 is configured basically similarly to the logic circuit CDRL. The logic circuit CDRL2 includes a data bus whose number of bits allows connection to both the latch circuits BCL0 and BCL1. The logic circuit CDRL2 includes, for example, a data bus whose number of bits is twice as many as the number of bits of the column address CA.

### Inter-Plane Copy Operation

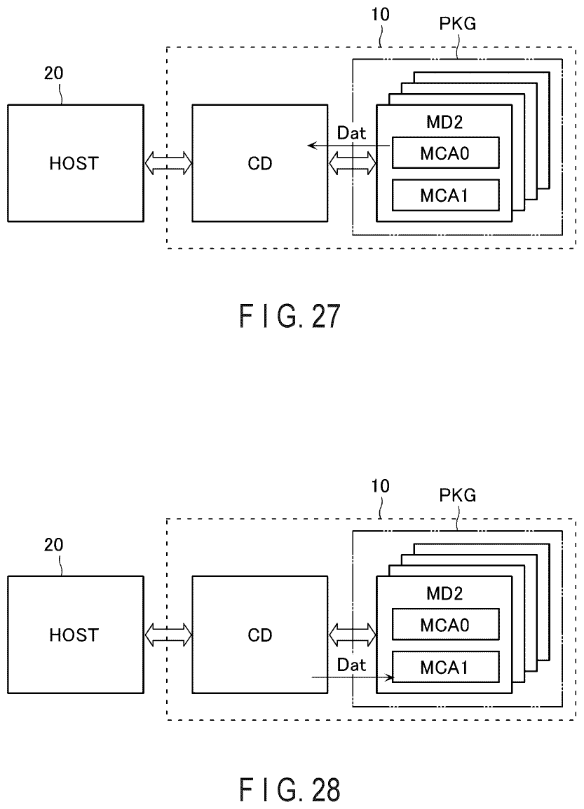

Next, referring to FIGS. 27 to 29, an inter-plane copy operation is described. FIGS. 27 to 29 are schematic block diagrams for illustrating the inter-plane copy operation.

To copy the user data Dat written in a certain memory cell array MCA (the memory cell array MCA0 in the illustrated example) in the memory die MD2 to another memory cell array MCA (the memory cell array MCA1 in the illustrated example) in the memory die MD2, for example, it is conceivable that first, the read operation and the data output described above are executed, and as shown in FIG. 27, the user data Dat is transferred from the memory cell array MCA0 to the controller die CD. It is conceivable that the write operation described above is subsequently executed, and as shown in FIG. 28, the read user data Dat is transferred to the memory cell array MCA1.

Here, while the operation corresponding to time t240 to time t244 described with reference to FIG. 14 (the operation of transferring the user data Dat from the memory die MD2 to the controller die CD) is in execution, the data bus between the controller die CD and the memory die MD2 is occupied. Consequently, at this timing, the operation corresponding to time t330 to time t333 described with reference to FIG. 15 (the operation of transferring the user data Dat from the controller die CD to the memory die MD2) cannot be executed.

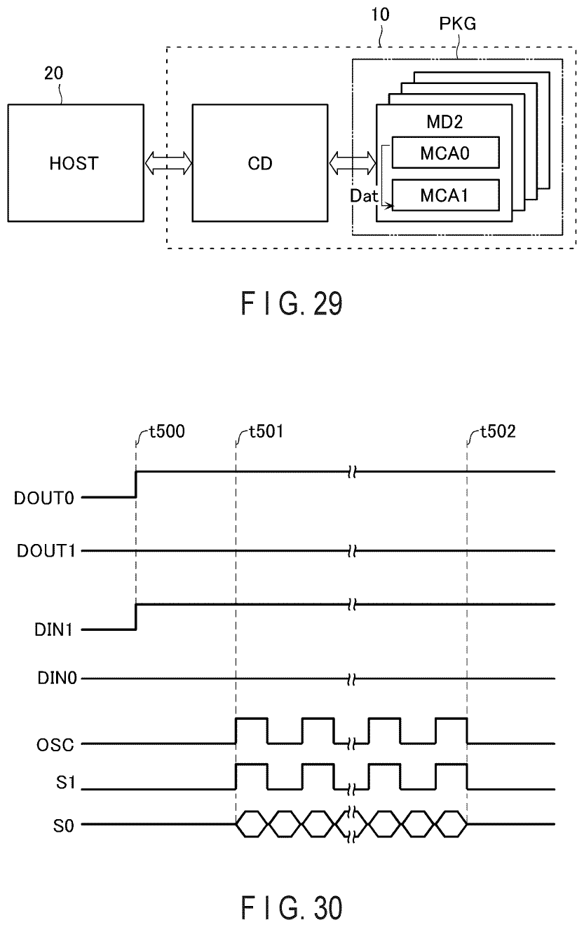

The memory die MD2 according to the present embodiment is configured to be capable of executing the inter-plane copy operation. As shown in FIG. 29, in the inter-plane copy operation, the user data Dat is directly transferred from the memory cell array MCA0 to the memory cell array MCA1 without intervention of the controller die CD. In this case, the operation corresponding to time t240 to time t244 described with reference to FIG. 14, and the operation corresponding to time t330 to time t333 described with reference to FIG. 15 are executed in parallel.

According to such a method, time required to copy the user data Dat between the memory cell arrays MCA0 and MCA1 can be greatly reduced.

In the inter-plane copy operation according to the present embodiment, the signal path between column decoder COLD and the data bus DB is electrically disconnected by multiplexer MPX2, and the user data Dat is not output to the data bus between the controller die CD and the memory die MD2. Furthermore, the input and output control circuit I/O does not input the signal on the data bus between the controller die CD and the memory die MD2 into the memory die MD2 that is executing the inter-plane copy operation. Consequently, at timing when one of the memory dies MD2 is executing the inter-plane copy operation, the controller die CD can input the user data Dat into another memory die MD2, and receive the user data Dat output from another memory die MD.

Note that in the inter-plane copy operation, the user data Dat output from the memory cell array MCA0 is not input into the controller die CD. The controller die CD does not output the user data Dat that is to be input into the memory cell array MCA1.

Next, referring to FIG. 30, the inter-plane copy operation is described in more detail. FIG. 30 is a schematic waveform diagram for illustrating the inter-plane copy operation.

Note that “DOUT0”, “DOUT1”, “DIN0”, and “DIN1” in the diagram respectively indicate signals on the signal lines DOUT0, DOUT1, DIN0, and DIN1. “OSC” indicates the timing signal output from the oscillation circuit OSC. “S1” indicates the timing signal transferred from the column decoder COLD corresponding to the memory cell array MCA0 to the column decoder COLD corresponding to the memory cell array MCA1. “S0” indicates the user data Dat transferred from the memory cell array MCA0 to the memory cell array MCA1.

Although not shown, similar to the case of the inter-chip copy operation, also in the inter-plane copy operation, the command set for reading the user data Dat from the memory cells MC in the memory cell array MCA0, and the command set for writing the user data Dat into the memory cells MC in the memory cell array MCA1 are input into the memory die MD2 according to the method as described with reference to FIG. 19.

At time t500 in FIG. 30, the signals on the signal lines DOUT0 and DIN1 rise from “L” to “H”. Accordingly, the transfer circuit TRC in the multiplexer MPX2 receives an instruction of the transfer direction of the user data Dat.

From time t501 to time t502, the oscillation circuit OSC outputs the timing signal. In conjunction with this, the column decoder COLD corresponding to the memory cell array MCA0 outputs the user data Dat in the latch circuit XDL0, with the timing signal, to the transfer circuit TRC. The transferred user data Dat is input into the column decoder COLD corresponding to the memory cell array MCA1, according to the timing signal transferred from the column decoder COLD corresponding to the memory cell array MCA0. The column decoder COLD corresponding to the memory cell array MCA0 transfers the transferred user data Dat to the latch circuit XDL1.

Note that the user data Dat in the memory cell array MCA0, and the timing signal are not output to the data bus between the controller die CD and the memory die MD2.

At the end of output of the timing signal at time t502, transfer of the user data Dat also ends.

Subsequently, the user data Dat in the latch circuit XDL1 is written into the memory cell array MCA1.

### Role of Logic Circuit CDRL2 in Inter-Plane Copy Operation

Next, the role of the logic circuit CDRL2 in the inter-plane copy operation is described.

From time t501 to time t502 in the inter-plane copy operation described with reference to FIG. 30, the multiplexer MPX2 (FIG. 26) accesses the sense amplifiers SA0 and SA1 in parallel. Consequently, it is required to select an appropriate bit with reference to the column address CA of the defective column in the memory cell array MCA0 stored in the latch circuit BCL0, and the column address CA of the defective column in the memory cell array MCA1 stored in the latch circuit BCL1 in parallel with each other.

Accordingly, the logic circuit CDRL2 includes a data bus whose number of bits allows connection to both the latch circuits BCL0 and BCL1.

### Other Embodiments

The semiconductor memory devices according to the first and second embodiments are described above. However, these are only examples, and the specific configuration and the like can be appropriately adjusted.

For example, similar to the memory die MD according to the second embodiment, the memory die MD according to the first embodiment may include an oscillation circuit OSC. In such a case, from time t460 to time t463 in the inter-chip copy operation, the controller die CD is not required to switch the input signals for the control terminals /RE and RE. The timing at which the user data Dat is output from the memory die MD0, and the timing at which the user data Dat is input into the memory die MD1 may be designated by the timing signal output from the oscillation circuit OSC.

In such a case, for example, it is conceivable that a plurality of switch circuits are provided between the system mounting board SSB and the packages PKG. In a case where the inter-chip copy operation is in execution in one of the packages PKG, it is conceivable that the one of the packages PKG is electrically disconnected from the system mounting board SSB. According to such a method, at timing when the one of the packages PKG is executing the inter-chip copy operation, the controller die CD can input the user data Dat into the memory die MD in another package PKG, and receive the user data Dat output from the memory die MD in another package PKG.

Likewise, the memory die MD2 may include no oscillation circuit OSC. In such a case, from time t501 to time t502 in the inter-plane copy operation, the controller die CD may switch the input signals for the control terminals /RE and RE. The timing at which the user data Dat is output from the memory die MD0, and the timing at which the user data Dat is input into the memory die MD1 may be designated by the input signals into the control terminals /RE and RE.

For example, the memory die MD2 may include no phase adjustment circuit PAC.

### Other

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory system comprising a controller and a plurality of memory chips, each of the memory chips including:
a memory cell array;
a first pad electrode;
a second pad electrode;
a phase adjustment circuit; and
a control circuit, wherein:
the first pad electrodes of the memory chips are commonly connected to a first pad electrode of the controller and the second pad electrodes of the memory chips are commonly connected to a second pad electrode of the controller; and
in response to a first command set input into a first memory chip among the memory chips to read data, and a second command set input into a second memory chip among the memory chips to write data,
the control circuit of the first memory chip executes reading of data from the memory cell array of the first memory chip and outputting of a data signal containing the read data through the first pad electrode of the first memory chip along with a timing signal output through the second pad electrode of the first memory chip, and concurrently therewith, the control circuit of the second memory chip executes receiving of a data signal containing write data through the first pad electrode of the second memory chip with reference to a timing signal received through the second pad electrode of the second memory chip and writing of the write data into the memory cell array of the second memory chip, and one or both of the phase adjustment circuit of the first memory chip and the phase adjustment circuit of the second memory chip adjust a phase of the data signal or the timing signal.

2. The memory system of claim 1, wherein
in response to the first command set and the second command set, the phase adjustment circuit of the first memory chip adjusts the phase of the timing signal output through the second pad electrode by one-half cycle.

3. The memory system of claim 1, wherein
in response to the first command set and the second command set, the phase adjustment circuit of the first memory chip adjusts the phase of the data signal output through the first pad electrode by one-half cycle.

4. The memory system of claim 1, wherein the read data contained in the data signal output from the first memory chip is not input into the controller.

5. The memory system of claim 1, wherein the write data contained in the data signal received by the second memory chip is not output by the controller.

6. The memory system of claim 1, wherein each of the memory chips further includes a third electrode pad electrode and the controller supplies a timing signal to the third electrode pad of the first memory chip after the first command set and the second command set are input.

7. The memory system of claim 6, wherein each of the memory chips further includes a fourth electrode pad and a fifth electrode pad, and the controller supplies command signals containing the first command set through the fourth and fifth electrode pads of the first memory chip and command signals containing the second command set through the fourth and fifth electrode pads of the second memory chip.

8. A semiconductor memory device, comprising:
a plurality of memory cell arrays;
a pad electrode through which data to be written into one of the memory cell arrays is to be input and through which data read from one of the memory cell arrays is to be output;
a data transfer circuit provided on a data transfer path between the plurality of memory cell arrays and the pad electrode;
a plurality of data input circuits, each of which is associated with one of the memory cell arrays, electrically connected to the data transfer circuit;
a plurality of data output circuits, each of which is associated with one of the memory cell arrays, electrically connected to the data transfer circuit;
a plurality of first signal lines, each of which is associated with one of the data input circuits, electrically connecting the corresponding data input circuit to the data transfer circuit;
a plurality of second signal lines, each of which is associated with one of the data output circuits, electrically connecting the corresponding data output circuit to the data transfer circuit; and
a control circuit configured to control the data transfer circuit to transfer a data signal transmitted through one of the first signal lines to the pad electrode or to one of the second signal lines.

9. The semiconductor memory device of claim 8, wherein the control circuit controls the data transfer circuit to transfer the data signal transmitted through one of the first signal lines to one of the second signal lines, in response to a first command set to read data from a first memory cell array among the memory cell arrays, and a second command set to write data into a second memory cell array among the memory cell arrays.

10. The semiconductor memory device of claim 9, wherein
in response to the first command set and the second command set, the control circuit activates the first signal line corresponding to the first memory cell array, and activates the second signal line corresponding to the second memory cell array.

11. The semiconductor memory device of claim 9, wherein
the data read from the first memory cell array in response to the first command set is not output through the pad electrode.

12. The semiconductor memory device of claim 9, wherein
the data written into the second memory cell array in response to the second command set is not input through the pad electrode.

13. The semiconductor memory device of claim 9, further comprising:
a plurality of decode circuits, each of which is associated with one of the memory cell arrays, provided on the data transfer path between the plurality of memory cell arrays and the data transfer circuit; and
a timing signal generation circuit that is electrically connected to the plurality of decode circuits, and configured to output a timing signal.

14. The semiconductor memory device of claim 13, wherein
in response to the first command set and the second command set, the timing signal generation circuit inputs the timing signal into the decode circuit corresponding to the first memory cell array.

15. The semiconductor memory device of claim 14, wherein
according to the timing signal, the decode circuit corresponding to the first memory cell array outputs, to the data transfer circuit, the data read from the first memory cell array.

16. The semiconductor memory device of claim 9, further comprising:
a plurality of registers, each of which is associated with one of the memory cell arrays and records column addresses of defective columns thereof;
a first data bus that is connectable to one of the registers, and is electrically connected to the data transfer circuit; and
a second data bus that is connectable to another of the registers, and is electrically connected to the data transfer circuit.

17. The semiconductor memory device of claim 16, wherein
in response to the first command set and the second command set, the data transfer circuit acquires the column address of the defective column corresponding to the first memory cell array through the first data bus, and acquires the column address of the defective column corresponding to the second memory cell array through the second data bus.

18. A method of performing an inter-chip copying of data in a memory system comprising
a controller and a plurality of memory chips, each of the memory chips including a memory cell array, a first pad electrode, and a second pad electrode, wherein the first pad electrodes of the memory chips are commonly connected to a first pad electrode of the controller and the second pad electrodes of the memory chips are commonly connected to a second pad electrode of the controller, said method comprising:
in response to a first command set input into a first memory chip among the memory chips to read data, and a second command set input into a second memory chip among the memory chips to write data,
executing, by the first memory chip, reading of data from the memory cell array of the first memory chip and outputting of a data signal containing the read data through the first pad electrode of the first memory chip along with a timing signal output through the second pad electrode of the first memory chip; and
concurrently with the executing by the first memory chip, executing, by the second memory chip, receiving of a data signal containing write data through the first pad electrode of the second memory chip with reference to a timing signal received through the second pad electrode of the second memory chip and writing of the write data into the memory cell array of the second memory chip, wherein
a phase of the data signal or the timing signal is adjusted during the executing by the first memory chip or the executing by the second memory chip.

19. The method of claim 18, wherein the read data contained in the data signal output from the first memory chip is not input into the controller.

20. The method of claim 18, wherein the write data contained in the data signal received by the second memory chip is not output by the controller.
